(19) United States
(12) Patent Application Publication
(10) Pub. No.: US 2026/0130098 A1
(43) Pub. Date: May 7, 2026

(54) DISPLAY MODULE, ELECTRONIC DEVICE, AND METHOD OF MANUFACTURING THE DISPLAY MODULE

(71) Applicant: Samsung Display Co., Ltd., Yongin-si (KR)

(72) Inventors: Yong Jun PARK, Yongin-si (KR); Young Suk Lee, Yongin-si (KR)

(73) Assignee: Samsung Display Co., Ltd., Yongin-si (KR)

(21) Appl. No.: 19/347,179

(22) Filed: Oct. 1, 2025

(30) Foreign Application Priority Data
Nov. 4, 2024 (KR) 10-2024-0153997

(51) Int. Cl. H10K 59/80; H10K 59/12

(52) U.S. Cl. CPC H10K 59/879; H10K 59/1201

(57) ABSTRACT

An electronic device includes a display panel and a light control layer disposed on the display panel. The light control layer includes a first refractive layer disposed on the display panel and a second refractive layer disposed on the first refractive layer. The first refractive layer has a refractive index in a range of about 1.2 to about 1.5 with respect to a visible light, the second refractive layer comprises a metamaterial, and the second refractive layer has a refractive index in a range of about -2.0 to about -0.1 with respect to the visible light.

### CROSS-REFERENCE TO RELATED APPLICATIONS

This application claims priority under 35 U.S.C. § 119 to and the benefit of Korean Patent Application No. 10-2024-0153997, filed on November 4, 2024 in the Korean Intellectual Property Office, the disclosure of which is incorporated by reference herein in its entirety.

### BACKGROUND

### 1. Field

The disclosure relates to a display module including a light control layer that controls a light with an emission angle greater than or equal to a selected angle, an electronic device, and a method of manufacturing the display module.

### 2. Description of Related Art

As the information society advances, the demand for display devices for presenting images is increasing in various forms. As an example, the display devices are being applied to various electronic devices such as smartphones, digital cameras, notebook computers, navigation units, and smart televisions. For example, the display devices may be applied to CIDs (Center Information Displays) positioned on the automobile’s instrument panel, center fascia, or dashboard.

Recently, research has been conducted on limiting the viewing angle of display devices to prevent driver distraction and to protect the personal information of personal electronic device users.

### SUMMARY

The disclosure provides a display module including a light control layer with improved front luminance and security.

The disclosure provides an electronic device including the light control layer with improved front luminance and security.

The disclosure provides a method of manufacturing the display module including the light control layer with improved front luminance and security.

According to an aspect of the disclosure, a display module may include a display panel and a light control layer disposed on the display panel. The light control layer may include a first refractive layer disposed on the display panel and a second refractive layer disposed on the first refractive layer. The first refractive layer may have a refractive index in a range of about 1.2 to about 1.5 nm with respect to a visible light, the second refractive layer may include a metamaterial, and the second refractive layer may have a refractive index in a range of about -2.0 to about -1.0 nm with respect to the visible light.

The light control layer may further include a third refractive layer disposed on the second refractive layer, and the third refractive layer may have a refractive index in a range of about 1.2 to about 1.5 with respect to the visible light.

Each of the first refractive layer and the third refractive layer may include at least one of SiO₂ and MgF₂.

Each of the first refractive layer and the third refractive layer may have a thickness in a range of about 10 nm to about 500 nm.

The light control layer may further include a plurality of refractive lenses disposed on the third refractive layer.

Each of the refractive lenses may include the metamaterial, and each of the refractive lenses may have a refractive index in a range of about -2.0 to about -0.1 with respect to the visible light.

The light control layer may further include a fourth refractive layer disposed on the third refractive layer, the fourth refractive layer may include the metamaterial, and the fourth refractive layer may have a refractive index greater than or equal to about -2.0 and smaller than or equal to about -0.1 with respect to the visible light.

The second refractive layer may include a plurality of lower refractive patterns, the lower refractive patterns may be spaced apart from each other, a separation space may be defined between the lower refractive patterns, and the third refractive layer may include a plurality of upper refractive patterns disposed on the lower refractive patterns, respectively.

Each of the lower refractive patterns may have a quadrangular shape in plan view.

Each of the lower refractive patterns has a side greater than or equal to about 10 nm and smaller than or equal to about 500 nm in plan view.

The lower refractive patterns may be spaced apart from each other by a distance in a range of about 50 nm to about 500 nm in plan view.

The second refractive layer may include at least one of a metal, a metal oxide, and a metal halide.

The second refractive layer may include at least one of Au, TiO₂, SiO₂, MgF, and Ta₂O₅.

The second refractive layer may have an extinction coefficient of zero (0) with respect to the visible light.

The second refractive layer may have a thickness greater than or equal to about 10 nm and smaller than or equal to about 300 nm.

According to another aspect of the disclosure, an electronic device may include a housing, a display module accommodated in the housing, and a window disposed on the display module. The display module may include a display panel and a light control layer disposed on the display panel. The light control layer may include a first refractive layer disposed on the display panel and a second refractive layer disposed on the first refractive layer. The first refractive layer may have a refractive index in a range of about 1.2 to about 1.5 with respect to a visible light, the second refractive layer may include a metamaterial, and the second refractive layer may have a refractive index in a range of about -2.0 to about -0.1 with respect to the visible light.

According to still another aspect of the disclosure, a method of manufacturing a display module may include forming a first refractive layer on a display panel and forming a second refractive layer on the first refractive layer. The first refractive layer may have a refractive index in a range of about 1.2 to about 1.5 with respect to a visible light, the second refractive layer may include a metamaterial, and the second refractive layer may have a refractive index in a range of about -2.0 to -0.1 with respect to the visible light.

The method may further include forming a third refractive layer on the second refractive layer after the forming of the second refractive layer.

The forming of the second refractive layer may include forming a preliminary second refractive layer on the first refractive layer and etching a portion of the preliminary second refractive layer to form a plurality of lower refractive patterns spaced apart from each other such that a separation space may be defined between the lower refractive patterns, and the forming of the third refractive layer may include forming a plurality of upper refractive patterns disposed on the lower refractive patterns, respectively.

The second refractive layer may include at least one of Au, TiO₂, SiO₂, MgF, and Ta₂O₅.

An electronic device may include a window and a display module manufactured by the method above.

### BRIEF DESCRIPTION OF DRAWINGS

FIG. 1 is a view illustrating an interior of an automobile to which an electronic device according to an embodiment of the disclosure is applied;

FIG. 2 is a view illustrating an image viewed from a driver’s seat when an electronic device according to an embodiment of the disclosure operates;

FIG. 3 is a view illustrating an image viewed from a front passenger’s seat when an electronic device according to an embodiment of the disclosure operates;

FIG. 4 is a view schematically illustrating a viewing angle of an image of an electronic device according to an embodiment of the disclosure;

FIGS. 5 and 6 are perspective views illustrating an electronic device according to an embodiment of the disclosure;

FIG. 7A is an exploded perspective view illustrating an electronic device according to an embodiment of the disclosure;

FIG. 7B is a block diagram illustrating an electronic device according to an embodiment of the disclosure;

FIG. 8 is a plan view illustrating a display module according to an embodiment of the disclosure;

FIGS. 9 to 11 are cross-sectional views taken along line I-I’ of FIG. 8;

FIG. 12 is an enlarged plan view illustrating area TT’ of FIG. 8;

FIG. 13 is a cross-sectional view taken along line II-II’ of FIG. 12;

FIG. 14 is an enlarged plan view illustrating area TT’ of FIG. 8;

FIG. 15 is a cross-sectional view taken along line III-III’ of FIG. 14;

FIGS. 16A and 16B are flowcharts illustrating a method of manufacturing a display module according to embodiments of the disclosure;

FIGS. 17 to 22 are cross-sectional views illustrating a method of manufacturing a display module according to an embodiment of the disclosure;

FIG. 23A is a graph illustrating results of a simulation of a light intensity of each of a display module of Comparative Example 1 and a display module of Example Embodiment 1 as a function of a viewing angle;

FIG. 23B is a cross-sectional view illustrating the display module of Comparative Example 1; and

FIG. 24 is a graph illustrating results of a simulation of a light efficiency of each of a display module of Comparative Example 2 and display modules of Example Embodiments 2 to 4 as a function of a viewing angle.

### DETAILED DESCRIPTION

The disclosure may be variously modified and realized in many different forms, and thus specific embodiments will be exemplified in the drawings and described in detail hereinbelow. However, the disclosure is not limited to the specific disclosed forms, and be construed to include all modifications, equivalents, or replacements included in the spirit and scope of the disclosure.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements are not limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise. As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

Spatially relative terms, such as “beneath”, “below”, “lower”, “above”, “upper” and the like, may be used herein for ease of description to describe one element or feature’s relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

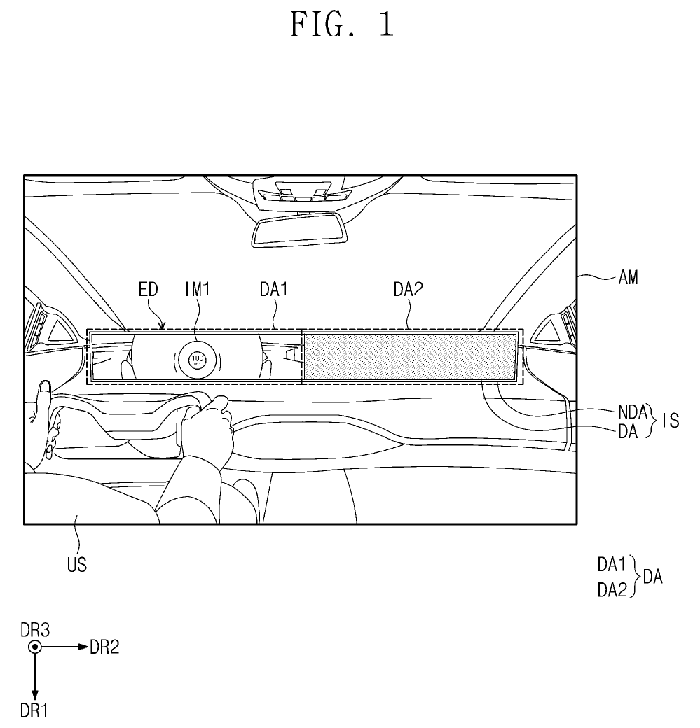

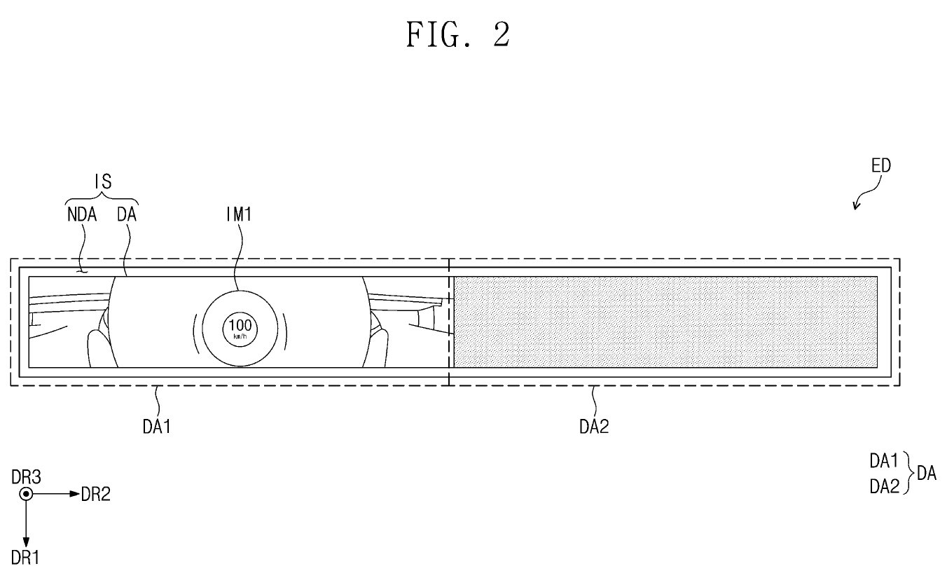

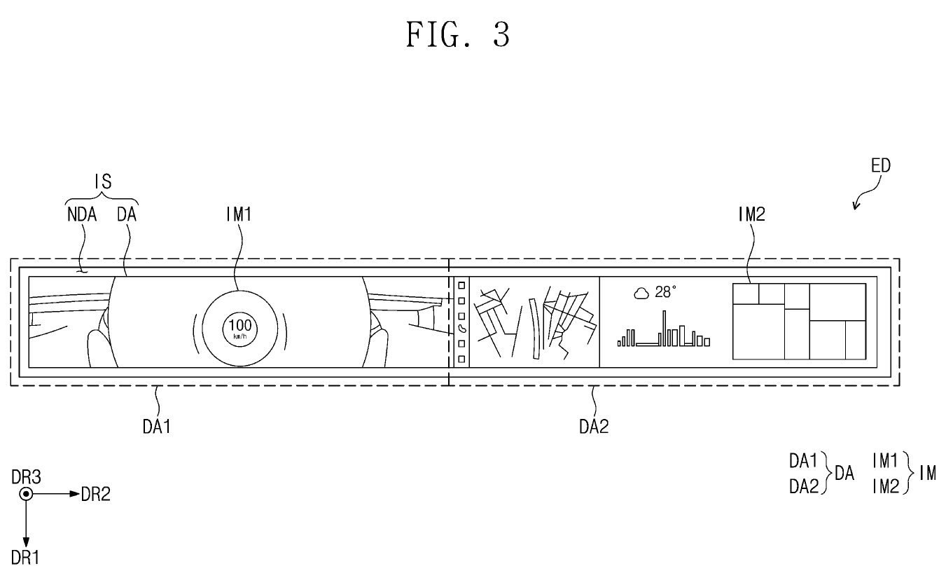

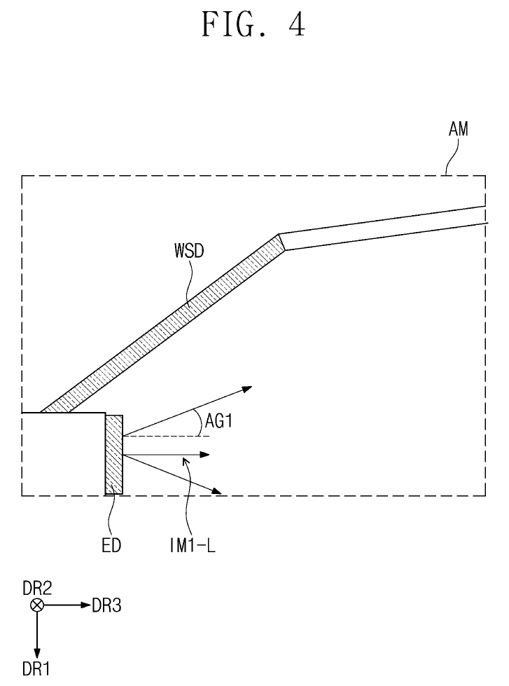

Hereinafter, an electronic device according to embodiments of the disclosure will be described with reference to accompanying drawings. FIG. 1 is a view illustrating an interior of an automobile to which an electronic device according to an embodiment of the disclosure is applied. FIG. 2 is a view illustrating an image viewed from a driver’s seat when the electronic device according to an embodiment of the disclosure operates. FIG. 3 is a view illustrating an image viewed from a front passenger’s seat when the electronic device according to an embodiment of the disclosure operates. FIG. 4 is a view schematically illustrating a viewing angle of the image of the electronic device according to an embodiment of the disclosure. FIGS. 1 and 2 illustrate the image of the electronic device, which is viewed from the driver’s seat, and FIG. 3 illustrates the image of the electronic device, which is viewed from the front passenger’s seat.

Referring to FIGS. 1 to 3, the electronic device ED may be installed inside the automobile AM. The electronic device ED may be activated in response to electrical signals. The electronic device ED may be applied to electronic devices, such as a mobile phone, a tablet computer, a smart watch, a notebook computer, a computer, a smart television, etc. The electronic device ED may be disposed inside the automobile AM to provide various information to a driver US.

The electronic device ED may display an image IM through a display surface IS substantially parallel to each of a first direction DR1 and a second direction DR2. The display surface IS, through which the image IM is displayed, may correspond to a front surface of the electronic device ED. The image IM may include a still image as well as a video. A third direction DR3 may indicate a normal line direction of the display surface IS, e.g., a thickness direction of the electronic device ED. Hereinafter, front (or upper) and rear (or lower) surfaces of each layer or each unit of the electronic device ED may be distinguished from each other in the third direction DR3.

In the disclosure, the first direction DR1 may be referred to as an up-down direction, the second direction DR2 may be referred to as a left-right direction, and the third direction DR3 may be referred to as the thickness direction.

The display surface IS of the electronic device ED may include a display area DA and a non-display area NDA. The image IM may be displayed through the display area DA. A user may view the image IM through the display area DA. In the embodiment, the display area DA is illustrated as a rectangular shape. However, this is an example, and the display area DA may have a variety of shapes and is not limited.

The non-display area NDA may be adjacent to the display area DA. The non-display area NDA may have a selected color. The non-display area NDA may surround the display area DA. Accordingly, the display area DA may have a shape substantially defined by the non-display area NDA, however, this is an example. The non-display area NDA may be disposed adjacent to a side of the display area DA or may be omitted. The electronic device ED according to the disclosure is not limited.

The display area DA may include a first display area DA1 and a second display area DA2. The first display area DA1 may be disposed in a position facing the driver’s seat and may provide the driver US with a first image IM1 necessary for driving while operating the automobile. The second display area DA2 may be disposed in a position facing the front passenger’s seat and may provide a second image IM2. As an example, the first image IM1 may display information such as speed, vehicle status, vehicle internal operation etc., and the second image IM2 may display various non-driving-related information as well as driving-related information such as navigation information.

The driver US may view the first image IM1 displayed in the first display area DA1 and may not view the second image IM2 displayed in the second display area DA2. Each of the first image IM1 of the first display area DA1 and the second image IM2 of the second display area DA2 may be viewed from the front passenger’s seat. A light generated from the first image IM1 of the first display area DA1 may travel to or reach both of the driver’s seat and the front passenger’s seat. A light generated from the second image IM2 of the second display area DA2 may travel to or reach the front passenger’s seat and may be blocked from reaching the driver’s seat. The driver US may avoid perceiving unnecessary information, such as the second image IM2, while driving.

FIGS. 1 and 2 illustrate a state in which the entire second display area DA2 is not visible to the driver US as a representative example, however, the disclosure is not limited thereto or thereby. According to an embodiment, a portion of the second display area DA2 may be visible, and the other portion of the second display area DA2 may be invisible. As an example, only driving-related information (e.g., navigation information) displayed in the portion of the second display area DA2 adjacent to the first display area DA1 may be visible to the driver US, and unnecessary information for driving displayed in the other portion of the second display area DA2 spaced apart from the first display area DA1 may be invisible to the driver US.

Referring to FIG. 4, a viewing angle AG1 of the first display area DA1 (refer to FIG. 2) may be restricted in the first direction (e.g., up-down direction) DR1. For example, a light IM1-L provided through the first display area DA1 (refer to FIG. 2) may be invisible at an angle greater than the viewing angle AG1. A path of the light IM1-L provided through the first display area DA1 may be restricted in the first direction (e.g., up-down direction) DR1, and thus, the light IM1-L may not reach a windshield WSD of the automobile AM. Accordingly, a reflected light occurring when the light IM1-L provided through the first display area DA1 (refer to FIG. 2) reaches the windshield WSD of the automobile AM may be invisible to the driver US, and thus, a safety may be ensured or enhanced.

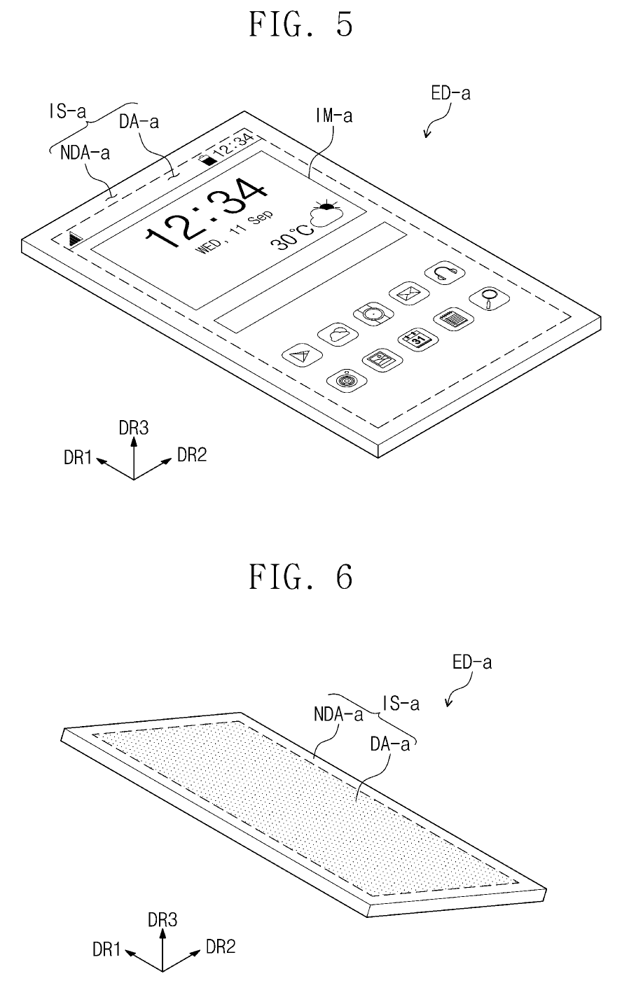

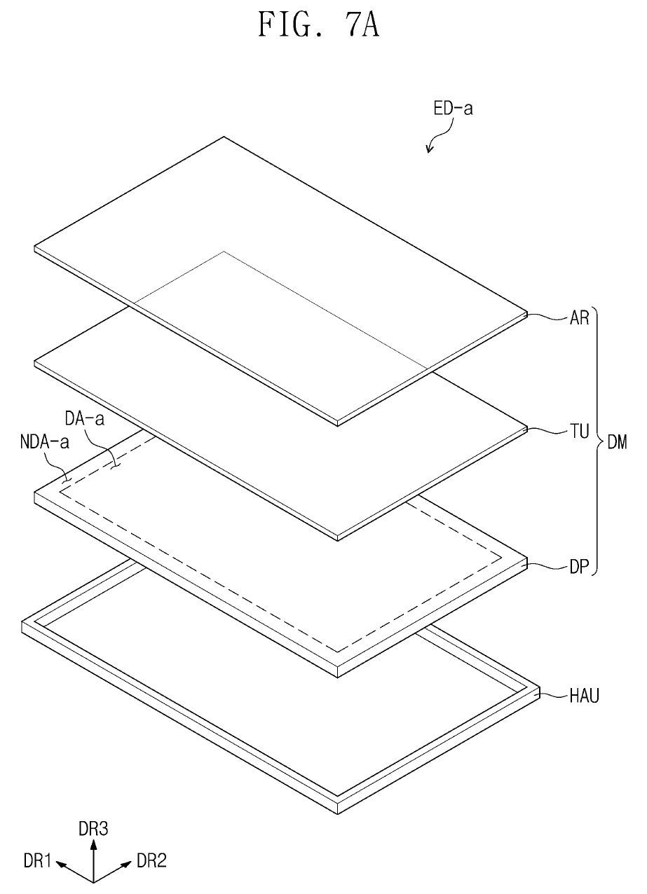

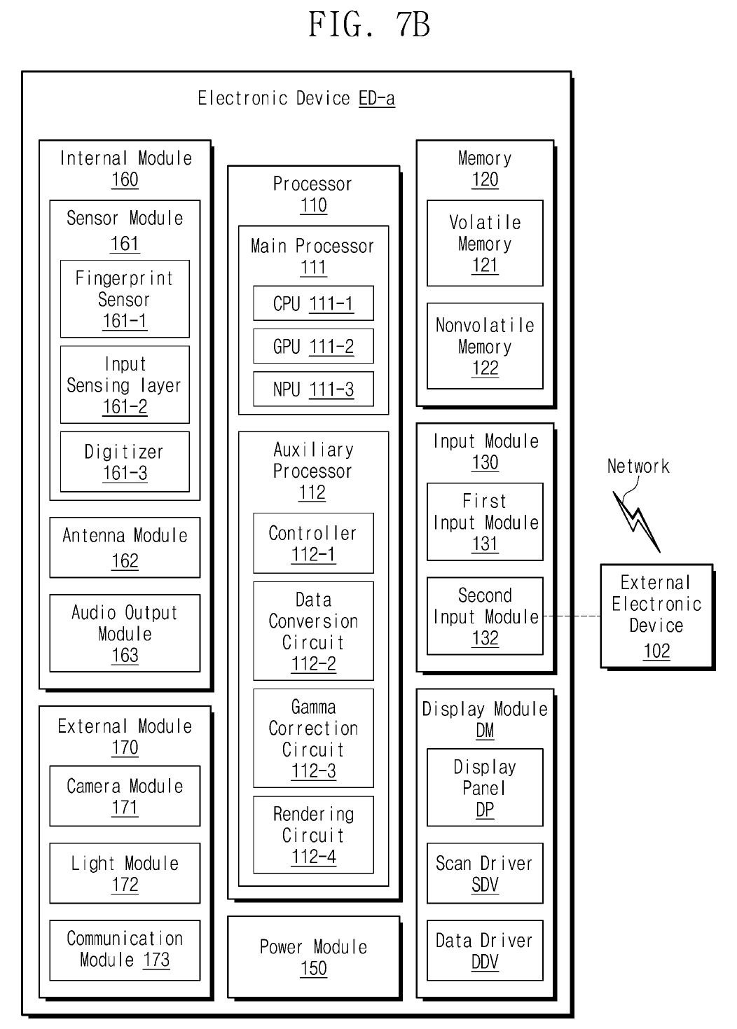

FIGS. 5 and 6 are perspective views illustrating an electronic device according to an embodiment of the disclosure. FIG. 7A is an exploded perspective view illustrating the electronic device according to an embodiment of the disclosure. FIG. 7B is a block diagram illustrating an electronic device according to an embodiment of the disclosure. FIG. 6 is a side perspective view of the electronic device shown in FIG. 5 as viewed from a different viewpoint. FIG. 7A is an exploded perspective view of the electronic device illustrated in FIGS. 5 and 6.

FIG. 5 shows a portable electronic device as a representative example of the electronic device ED-a, however, the disclosure is not limited thereto or thereby. The electronic device ED-a may be applied to a large-sized electronic product, such as a television set, a monitor, or an outdoor billboard, and a small-sized or medium-sized electronic product, such as a personal computer, a notebook computer, a personal digital assistant, a car navigation unit, a game unit, a smartphone, a tablet computer, and a camera. However, these are examples, and the electronic device ED-a may be applied to other electronic devices as long as they do not depart from the invention.

The electronic device ED-a may have a cuboidal shape having a thickness in the third direction DR3 on a plane defined by the first direction DR1 and the second direction DR2 intersecting the first direction DR1. However, this is an example, and the electronic device ED-a may have a variety of shapes.

According to an embodiment, upper (or front) and lower (or rear) surfaces of each member may be defined with respect to a direction in which an image IM-a is displayed. The front and rear surfaces may be opposite to each other in the third direction DR3, and a normal line direction of each of the upper and lower surfaces may be substantially parallel to the third direction DR3.

Directions indicated by the first, second, and third directions DR1, DR2, and DR3 may be relative to each other and may be changed to other directions.

The electronic device ED-a may display the image IM-a through a display surface IS-a. The display surface IS-a may include a display area DA-a in which the image IM-a is displayed and a non-display area NDA-a defined adjacent to the display area DA-a. The image IM-a may not be displayed through the non-display area NDA-a. The image IM-a may include a video and a still image. FIG. 5 illustrates a plurality of application icons and a clock widget as representative examples of the image IM-a.

The display area DA-a may have a quadrangular shape. The non-display area NDA-a may surround the display area DA-a. However, embodiments are not limited thereto or thereby, and the shape of the display area DA-a and the shape of the non-display area NDA-a may be designed relative to each other. For example, the non-display area NDA-a may not be disposed on a front surface of the electronic device ED-a.

The electronic device ED-a may be flexible. The term “flexible” used herein refers to the property of being able to be bent, and the flexible display device may include all structures from a structure that is completely bent to a structure that is bent at the scale of a few nanometers. For example, the electronic device ED-a may be a curved electronic device or a foldable electronic device, however, embodiments are not limited thereto or thereby. According to an embodiment, the electronic device ED-a may be rigid.

Referring to FIGS. 5 and 6, a luminance rate of the electronic device ED-a may be changed according to a user’s line of sight. When the user is looking at the display area DA-a of the electronic device ED-a in front of the electronic device ED-a, the luminance rate of the electronic device ED-a, which is perceived by the user, may be maximized. When the user is looking at the display area DA-a of the display device at a side of the electronic device ED-a, e.g., when an angle (hereinafter, referred to as a viewing angle) between the user’s line of sight and the display area DA-a is smaller than about 90 degrees, the luminance rate of the electronic device ED-a, which is perceived by the user, may be reduced. As an example, when the viewing angle is smaller than or equal to about 45 degrees, the luminance rate of the electronic device ED-a decreases to less than about 1% compared with the viewing angle of about 90 degrees, and thus, the image IM-a may not be recognizable to the user as will be described later.

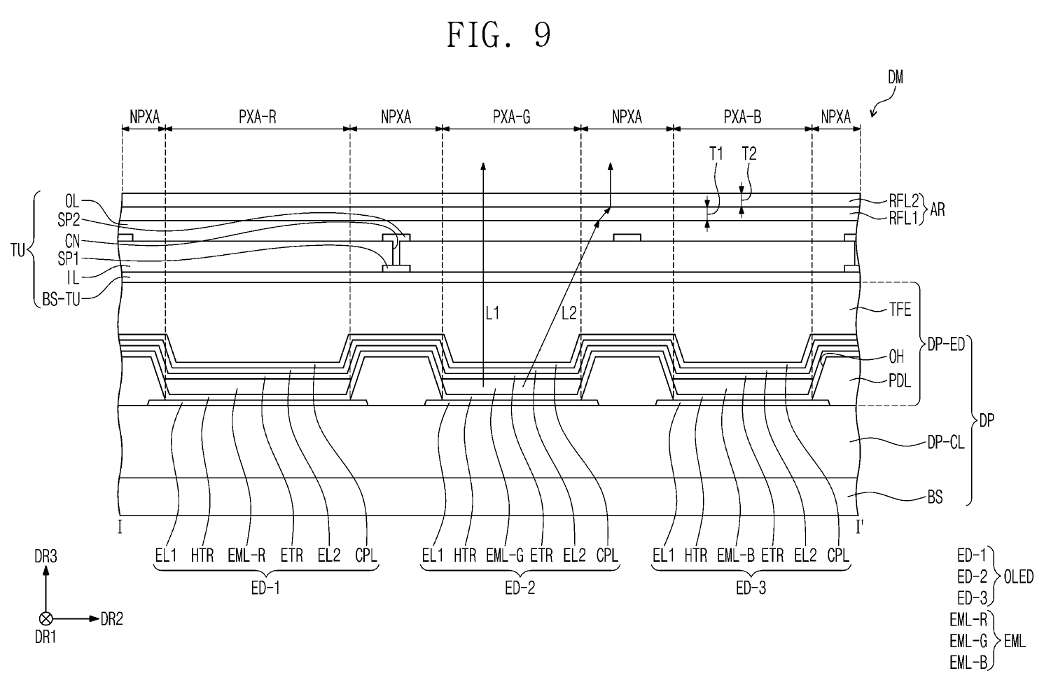

According to the disclosure, since the electronic device ED-a includes a plurality of light control layers AR (refer to FIG. 9), a relative proportion of light directed to the third direction DR3 (hereinafter, referred to as a front luminance rate) with respect to a total amount of light generated by the electronic device ED-a may be improved, while the amount of light directed toward lateral sides may be reduced, thereby enhancing the security of the electronic device ED-a.

FIG. 7A is an exploded perspective view of the electronic device ED-a according to an embodiment of the disclosure. Referring to FIG. 7A, the electronic device ED-a may include a housing HAU and a display module DM, which are sequentially stacked in the third direction DR3. The display module DM may include a display panel DP and the light control layer AR. The display module DM may further include a sensor layer TU disposed between the display panel DP and the light control layer AR.

The housing HAU may accommodate the display panel DP, the sensor layer TU, and the light control layer AR.

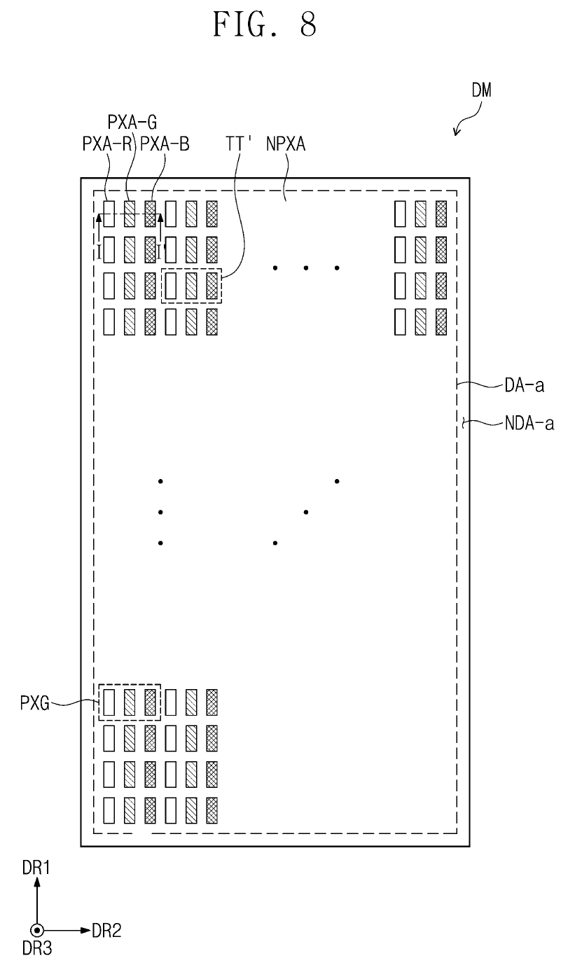

The display panel DP may include pixels in an area corresponding to the display area DA-a. The pixels may correspond to a plurality of pixel areas PXA-R, PXA-B, and PXA-G (refer to FIG. 8). The pixels may generate lights in response to electrical signals. The display area DA-a may display the image IM-a corresponding to the lights generated by the pixels.

According to an embodiment, the display panel DP may be a self-luminous display panel. As an example, the display panel DP may be a micro-LED display panel, a nano-LED display panel, an organic light emitting display panel, or a quantum dot light emitting display panel. However, this is an example. The display panel DP is not limited thereto or thereby as long as the display panel DP is the self-luminous display panel.

A light emitting layer of the organic light emitting display panel may include an organic light emitting material. A light emitting layer of the quantum dot light emitting display panel may include a quantum dot and/or a quantum rod. The micro-LED display panel may include a micro light-emitting diode element that is an ultra-small light-emitting element, and the nano-LED display panel may include a nano light-emitting diode element. Hereinafter, the organic light emitting display panel will be described as the display panel DP. The components of the display panel DP will be described in detail with reference to FIG. 9.

The light control layer AR may be disposed on the display panel DP. The light control layer AR may refract the light traveling to the lateral sides of the electronic device ED-a and may increase the front luminance rate. The structures and functions of the light control layer AR will be described in detail with reference to FIG. 9.

The sensor layer TU may be disposed between the display panel DP and the light control layer AR. The sensor layer TU may obtain information required to generate the image IM-a (refer to FIG. 5) in the display panel DP in response to an external input applied thereto. The external input may be a user input. The user input may include various forms of external inputs, such as a part of a user’s body, light, heat, pen, or pressure.

FIG. 7B is a block diagram of the electronic device according to an embodiment of the disclosure.

Referring to FIG. 7B, the electronic device ED-a may communicate with an external electronic device 102 through a network (for example, a short-range wireless communication network or a long-range wireless communication network). According to an embodiment, the electronic device ED-a may include a processor 110, a memory 120, an input module 130, the display module DM, a power module 150, an internal module 160, and an external module 170. According to an embodiment, in the electronic device ED-a, at least one of the above-described components may be omitted or one or more other components may be added. According to an embodiment, some of the above-described components (for example, a sensor module 161, an antenna module 162, or an audio output module 163) may be integrated into another component (for example, the display module DM).

The processor 110 may execute software to control at least another component (for example, a hardware or software component) of the electronic device ED-a connected to the processor 110 and may perform various data processing or operations. According to an embodiment, as at least a portion of the data processing or operations, the processor 110 may store commands or data received from other components (for example, the input module 130, the sensor module 161, or a communication module 173) in a volatile memory 121, may process the commands or the data stored in the volatile memory 121, and may store result data in a nonvolatile memory 122.

The processor 110 may include a main processor 111 and an auxiliary processor 112. The main processor 111 may include one or more of a central processing unit (CPU) 111-1 or an application processor (AP). The main processor 111 may further include any one or more of a graphics processing unit (GPU) 111-2, a communication processor (CP), and an image signal processor (ISP).

The main processor 111 may further include a neural processing unit (NPU) 111-3. The NPU may be a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more of the above, but is not limited to the above-described example. Additionally or alternatively, the artificial intelligence model may include a software structure in addition to a hardware structure. At least two of the above-described processing units and processors may be implemented as a single integrated component (for example, a single chip) or as separate components (for example, a plurality of chips).

The auxiliary processor 112 may include a controller 112-1. The controller 112-1 may include an interface conversion circuit and a timing control circuit. The controller 112-1 may receive an image signal from the main processor 111, convert a data format of the image signal to be suitable for an interface specification of the display module DM, and output image data. The controller 112-1 may output various control signals to drive the display module DM.

The auxiliary processor 112 may further include a data conversion circuit 112-2, a gamma correction circuit 112-3, a rendering circuit 112-4, and the like. The data conversion circuit 112-2 may receive the image data from the controller 112-1, compensate for the image data to display an image with a selected luminance based on characteristics of the electronic device ED-a, user settings, or the like, or convert the image data to reduce power consumption or to compensate for image retention.

The gamma correction circuit 112-3 may convert the image data, a gamma reference voltage, or the like so that the image displayed on the electronic device ED-a may have a selected gamma characteristic. The rendering circuit 112-4 may receive the image data from the controller 112-1 and render the image data taking into account a pixel arrangement or the like of the display panel DP applied to the electronic device ED-a.

At least one of the data conversion circuit 112-2, the gamma correction circuit 112-3, and the rendering circuit 112-4 may be integrated into another component (for example, the main processor 111 or the controller 112-1). At least one of the data conversion circuit 112-2, the gamma correction circuit 112-3, and the rendering circuit 112-4 may be integrated into a data driver DDV, which is described later.

The memory 120 may store various data used by at least one component (for example, the processor 110 or the sensor module 161) of the electronic device ED-a and input or output data associated with corresponding commands. The memory 120 may include at least one of the volatile memory 121 and the nonvolatile memory 122.

The input module 130 may receive commands or data to be used by a component (for example, the processor 110, the sensor module 161, or the audio output module 163) of the electronic device ED-a from an external source (for example, the user or the external electronic device 102) of the electronic device ED-a.

The input module 130 may include a first input module 131 receiving commands or data from the user and a second input module 132 receiving commands or data from the external electronic device 102. The first input module 131 may include a microphone, a mouse, a keyboard, a key (for example, a button), or a pen (for example, a passive pen or an active pen).

The second input module 132 may support a designated protocol that enables connection to the external electronic device 102 via a wired connection or wireless connection. According to an embodiment, the second input module 132 may include a high definition multimedia interface (HDMI), a universal serial bus (USB) interface, an SD card interface, or an audio interface. The second input module 132 may include a connector capable of physically connecting to the external electronic device 102, for example, an HDMI connector, a USB connector, an SD card connector, or an audio connector (for example, a headphone connector).

The display module DM may provide visual information to the user. The display module DM may include the display panel DP, a scan driver SDV, and the data driver DDV. The display module DM may further include a window, a chassis, and a bracket to protect the display panel DP.

The display panel DP may include a liquid crystal display panel, an organic light emitting display panel, or an inorganic light emitting display panel, and a type of the display panel DP is not limited. The display panel DP may be a rigid type or a flexible type that is rollable or foldable. The display module DM may further include a supporter, a bracket, a heat dissipation member, or the like that supports the display panel DP.

The scan driver SDV may be mounted on the display panel DP as a driving chip. For example, the scan driver SDV may be integrated into the display panel DP. For example, the scan driver SDV may include an amorphous silicon thin-film transistor (TFT) gate driver circuit (ASG), a low temperature polycrystalline silicon (LTPS) TFT gate driver circuit, or an oxide semiconductor TFT gate driver circuit (OSG) embedded in the display panel DP. The scan driver SDV may receive a control signal from the controller 112-1 and output scan signals to the display panel DP in response to the control signal.

The display panel DP may further include an emission driver. The emission driver may output an emission control signal to the display panel DP in response to a control signal received from the controller 112-1. The emission driver may be formed separately from the scan driver SDV or may be integrated into the scan driver SDV.

The data driver DDV may receive a control signal from the controller 112-1, convert image data into an analog voltage (for example, a data voltage) in response to the control signal, and then output the data voltages to the display panel DP.

The data driver DDV may be integrated into another component (for example, the controller 112-1). A function of the interface conversion circuit and the timing control circuit of the controller 112-1 described above may be integrated into the data driver DDV.

The display module DM may further include the emission driver, a voltage generation circuit, and the like. The voltage generation circuit may output various voltages to drive the display panel DP.

The power module 150 may supply power to components of the electronic device ED-a. The power module 150 may include a battery that charges a power voltage. The battery may include a non-rechargeable primary cell, a rechargeable secondary cell, or fuel cell. The power module 150 may include a power management integrated circuit (PMIC). The PMIC may supply optimized power to each of the above-described modules and modules described later. The power module 150 may include a wireless power transmission/reception member electrically connected to the battery. The wireless power transmission/reception member may include a plurality of coil-type antenna radiators.

The electronic device ED-a may further include the internal module 160 and the external module 170. The internal module 160 may include the sensor module 161, the antenna module 162, and the audio output module 163. The external module 170 may include a camera module 171, a light module 172, and the communication module 173.

The sensor module 161 may sense an input by a body of the user or an input by a pen among the first input module 131 and may generate an electrical signal or a data value corresponding to the input. The sensor module 161 may include at least one of a fingerprint sensor 161-1, an input sensing layer 161-2, and a digitizer 161-3.

The fingerprint sensor 161-1 may generate a data value corresponding to a fingerprint of the user. The fingerprint sensor 161-1 may include any one of an optical type fingerprint sensor or a capacitive type fingerprint sensor.

The input sensing layer 161-2 may generate a data value corresponding to coordinate information of the input by the body of the user or the input by the pen. The input sensing layer 161-2 may generate the data value based on changes in capacitance caused by the input. The input sensing layer 161-2 may sense an input by the passive pen or may transmit/receive data to and from the active pen.

The input sensing layer 161-2 may measure a biometric signal such as blood pressure, hydration levels, or body fat. For example, when the user touches a part of their body to a sensor layer or a sensing panel and remains still for a certain period, the input sensing layer 161-2 may sense the biometric signal based on changes in an electric field caused by the body part and output information selected by the user to the display module DM.

The digitizer 161-3 may generate a data value corresponding to coordinate information of the input by the pen. The digitizer 161-3 may generate the data value based on changes in an electromagnetic field caused by the input. The digitizer 161-3 may sense the input by the passive pen or may transmit/receive data to and from the active pen.

At least one of the fingerprint sensor 161-1, the input sensing layer 161-2, and the digitizer 161-3 may be implemented as a sensor layer formed on the display panel DP through a continuous process. The fingerprint sensor 161-1, the input sensing layer 161-2, and the digitizer 161-3 may be disposed above the display panel DP, and any one of the fingerprint sensor 161-1, the input sensing layer 161-2, and the digitizer 161-3, for example, the digitizer 161-3, may be disposed below the display panel DP.

At least two of the fingerprint sensor 161-1, the input sensing layer 161-2, and the digitizer 161-3 may be integrated into a single sensing panel using the same process. When at least two of the fingerprint sensor 161-1, the input sensing layer 161-2, and the digitizer 161-3 are integrated into a sensing panel, the sensing panel may be disposed between the display panel DP and the window disposed above the display panel DP. According to an embodiment, the sensing panel may be disposed on the window, and a position of the sensing panel is not limited.

At least one of the fingerprint sensor 161-1, the input sensing layer 161-2, and the digitizer 161-3 may be embedded in the display panel DP. For example, at least one of the fingerprint sensor 161-1, the input sensing layer 161-2, and the digitizer 161-3 may be simultaneously formed through a process of forming elements (for example, a light emitting element, a transistor, and the like) included in the display panel DP.

For example, the sensor module 161 may generate an electrical signal or a data value corresponding to an internal state or an external state of the electronic device ED-a. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit a signal or power to an external source or to receive a signal or power from the external source. According to an embodiment, the communication module 173 may transmit a signal to an external electronic device or may receive a signal from an external electronic device through an antenna suitable for a communication method. An antenna pattern of the antenna module 162 may be integrated into a component (for example, the display panel DP) of the display module DM or the input sensing layer 161-2.

The audio output module 163 may be a device to output an audio signal to an outside of the electronic device ED-a and, for example, may include a speaker used for general purposes such as multimedia playback or recording playback and a receiver used exclusively to receive a phone call. According to an embodiment, the receiver may be integral with or separately from the speaker. An audio output pattern of the audio output module 163 may be integrated into the display module DM.

The camera module 171 may capture a still image and a video. According to an embodiment, the camera module 171 may include one or more lenses, an image sensor, or an image signal processor. The camera module 171 may further include an infrared camera capable of measuring presence or absence of the user, a position of the user, a gaze of the user, and the like.

The light module 172 may provide light. The light module 172 may include a light emitting diode or a xenon lamp. The light module 172 may operate in conjunction with the camera module 171 or may operate independently.

The communication module 173 may support the establishment of a wired or wireless communication channel between the electronic device ED-a and the external electronic device 102 and communication through the established communication channel. The communication module 173 may include one or both of a wireless communication module such as a cellular communication module, a short-range wireless communication module, or a global navigation satellite system (GNSS) communication module, and a wired communication module such as a local area network (LAN) communication module or a power line communication module. The communication module 173 may communicate with the external electronic device 102 through a short-range communication network such as Bluetooth, WiFi direct, or infrared data association (IrDA), or a long-range communication network such as a cellular network, the Internet, or a computer network (for example, LAN or WAN). The above-described various types of communication modules 173 may be implemented as a single chip or as separate chips.

The input module 130, the sensor module 161, the camera module 171, and the like may be used in conjunction with the processor 110 to control an operation of the display module DM.

The processor 110 may output commands or data to the display module DM, the audio output module 163, the camera module 171, or the light module 172 based on input data received from the input module 130. For instance, the processor 110 may generate image data in response to the input data applied through the mouse, the active pen, or the like and output the image data to the display module DM or may generate command data in response to the input data and output the command data to the camera module 171 or the light module 172. When no input data is received from the input module 130 for a certain period of time, the processor 110 may switch an operation mode of the electronic device ED-a to a low power mode or a sleep mode to reduce or minimize power consumption of the electronic device ED-a.

The processor 110 may output commands or data to the display module DM, the audio output module, the camera module 171, or the light module 172 based on sensing data received from the sensor module 161. For instance, the processor 110 may compare authentication data applied by the fingerprint sensor 161-1 with authentication data stored in the memory 120 and then execute an application according to a comparison result. The processor 110 may execute the command based on sensing data sensed by the input sensing layer 161-2 or the digitizer 161-3 or may output corresponding image data to the display module DM. When the sensor module 161 includes a temperature sensor, the processor 110 may receive temperature data measured by the sensor module 161 and further perform luminance correction or the like on the image data based on the temperature data.

The processor 110 may receive measurement data regarding the presence or absence of the user, the position of the user, the gaze of the user, and the like, from the camera module 171. The processor 110 may further perform luminance correction or the like to the image data based on the measurement data. For instance, when the processor 110 determines the presence or absence of the user through an input from the camera module 171, the processor 110 may output image data whose luminance is corrected through the data conversion circuit 112-2 or the gamma correction circuit 112-3 to the display module DM.

Among the above-described components, some components may be connected to each other through a communication method between peripheral devices, for example, a bus, general purpose input/output (GPIO), a serial peripheral interface (SPI), a mobile industry processor interface (MIPI), or an ultra path interconnect (UPI) link to exchange a signal (for example, commands or data) with each other. The processor 110 may communicate with the display module DM through a mutually agreed interface, for example, any one of the above-described communication methods, and the communication method is not limited to the above-described communication method.

The electronic device ED-a according to various embodiments of the disclosure may be applied to various types of devices. The electronic device ED-a may include, for example, at least one of a portable communication device (e.g., a smartphone), a computer device, a portable multimedia device, a portable medical device, a camera, a wearable device, and a home appliance device. The electronic device ED-a according to various embodiments of the disclosure is not limited to the above-described devices.

FIG. 8 is a plan view illustrating the display module according to an embodiment of the disclosure. FIGS. 9 to 11 are cross-sectional views taken along line I-I’ of FIG. 8.

Referring to FIGS. 8 and 9, the display module DM may include the display panel DP and the light control layer AR. The display module DM may further include the sensor layer TU. As the display module DM includes both the display panel DP and the sensor layer TU, the display module DM may sense the external input while displaying the image IM-a (refer to FIG. 5).

The display panel DP may include a base substrate BS, a circuit layer DP-CL, and a display element layer DP-ED, which are sequentially stacked. The display element layer DP-ED may include a pixel definition layer PDL, light emitting elements OLED disposed in pixel openings OH defined through (or formed in) the pixel definition layer PDL, and an encapsulation layer TFE disposed on the light emitting elements OLED.

The base substrate BS may be rigid or flexible. The base substrate BS may be a polymer substrate, a plastic substrate, a glass substrate, a metal substrate, or a composite material substrate. The base substrate BS may have a single-layer structure or a multi-layer structure. The base substrate BS may include a synthetic resin film, and the base substrate BS may have a multi-layer structure of multiple synthetic resin films. The synthetic resin film may include a polyimide-based resin, an acrylic-based resin, a vinyl-based resin, an epoxy-based resin, a urethane-based resin, a cellulose-based resin, and a perylene-based resin, however, a material of the synthetic resin film is not limited thereto or thereby.

The circuit layer DP-CL may be disposed on the base substrate BS. The circuit layer DP-CL may include an insulating layer, a semiconductor pattern, a conductive pattern, and a signal line. The circuit layer DP-CL may include a plurality of transistors formed by the semiconductor pattern, the conductive pattern, and the signal line. Each of the transistors may include a control electrode, an input electrode, and an output electrode. For example, the circuit layer DP-CL may include a switching transistor and a driving transistor to drive the light emitting element OLED.

The display element layer DP-ED may be disposed on the circuit layer DP-CL. The display element layer DP-ED may include the pixel definition layer PDL, the light emitting element OLED, and the encapsulation layer TFE.

The light emitting element OLED may include a plurality of light emitting elements ED-1, ED-2, and ED-3. Each of the light emitting elements ED-1, ED-2, and ED-3 may include a first electrode EL1, a hole transport region HTR, a corresponding light emitting layer of the light emitting layers EML-R, EML-G, and EML-B, an electron transport region ETR, a second electrode EL2, and a capping layer CPL. A first light emitting element ED-1 may include a first light emitting layer EML-R overlapping a first pixel area PXA-R. A second light emitting element ED-2 may include a second light emitting layer EML-G overlapping a second pixel area PXA-G. A third light emitting element ED-3 may include a third light emitting layer EML-B overlapping a third pixel area PXA-B.

The pixel definition layer PDL may be disposed on the circuit layer DP-CL. The pixel openings OH may be defined through (or formed in) the pixel definition layer PDL. The pixel openings OH may correspond to the pixel areas PXA-R, PXA-G, and PXA-B, respectively. A light shielding area NPXA may be defined between the pixel areas PXA-R, PXA-G, and PXA-B adjacent to each other and may correspond to the pixel definition layer PDL.

The pixel definition layer PDL may have a light absorbing property. For example, the pixel definition layer PDL may have a black color. The pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light shielding pattern having a light shielding property.

The pixel definition layer PDL may include an organic resin or an inorganic material. As an example, the pixel definition layer PDL may include a polyacrylate-based resin, a polyimide-based resin, silicon nitride (SiNₓ), silicon oxide (SiOₓ), or silicon oxynitride (SiOₓN_{y}).

FIG. 9 shows a structure in which the light emitting layers EML-R, EML-G, and EML-B of the light emitting elements ED-1, ED-2, and ED-3 are disposed in the pixel openings OH defined through (or formed in) the pixel definition layer PDL and the hole transport region HTR, the electron transport region ETR, the second electrode EL2, and the capping layer CPL are commonly disposed in the light emitting elements ED-1, ED-2, and ED-3. However, the disclosure is not limited thereto or thereby. Unlike the structure shown in FIG. 9, the hole transport region HTR, the electron transport region ETR, the second electrode EL2, and the capping layer CPL may be disposed in the pixel openings OH defined through (or formed in) the pixel definition layer PDL after being patterned. As an example, according to an embodiment, at least one of the hole transport region HTR, the light emitting layers EML-R, EML-G, and EML-B, the electron transport region ETR, the second electrode EL2, and the capping layer CPL of the light emitting elements ED-1, ED-2, and ED-3 may be patterned by an inkjet printing method.

In the light emitting element OLED, the first electrode EL1 may be disposed on the circuit layer DP-CL. The first electrode EL1 may be an anode or a cathode. For example, the first electrode EL1 may be a pixel electrode. The first electrode EL1 may be a transmissive electrode, a transflective electrode, or a reflective electrode.

The hole transport region HTR may be disposed between the first electrode EL1 and the light emitting layer EML. The hole transport region HTR may include at least one of a hole injection layer, a hole transport layer, and an electron block layer. The hole transport region HTR may be commonly disposed to overlap the pixel areas PXA-R, PXA-G, and PXA-B and the pixel definition layer PDL, which is disposed between the pixel areas PXA-R, PXA-G, and PXA-B to distinguish the pixel areas PXA-R, PXA-G, and PXA-B from each other, however, the disclosure is not limited thereto or thereby. According to an embodiment, the hole transport region HTR may be patterned into a plurality of portions to be respectively disposed in the pixel areas PXA-R, PXA-G, and PXA-B.

The light emitting layer EML may be disposed on the first electrode EL1. The light emitting layer EML may include the light emitting layers EML-R, EML-G, and EML-B. The first light emitting layer EML-R may overlap the first pixel area PXA-R and may emit a first light. The second light emitting layer EML-G may overlap the second pixel area PXA-G and may emit a second light. The third light emitting layer EML-B may overlap the third pixel area PXA-B and may emit a third light. The first, second, and third lights respectively emitted from the light emitting elements ED-1, ED-2, and ED-3 may have different wavelength ranges from each other. As an example, the first light may be a red light within a wavelength range greater than or equal to about 625 nm and smaller than or equal to about 675 nm. As an example, the second light may be a green light within a wavelength range greater than or equal to about 500 nm and smaller than or equal to about 570 nm. The third light may be a blue light within a wavelength range greater than or equal to about 410 nm and smaller than or equal to about 480 nm.

The electron transport region ETR may be disposed between the light emitting layer EML and the second electrode EL2. The electron transport region ETR may include at least one of an electron injection layer, an electron transport layer, and a hole block layer. The electron transport region ETR may be commonly disposed to overlap the pixel areas PXA-R, PXA-G, and PXA-B and the pixel definition layer PDL, which is disposed between the pixel areas PXA-R, PXA-G, and PXA-B to distinguish the pixel areas PXA-R, PXA-G, and PXA-B from each other, however, the disclosure is not limited thereto or thereby. According to an embodiment, the electron transport region ETR may be patterned into a plurality of portions to be respectively disposed in the pixel areas PXA-R, PXA-G, and PXA-B.

The second electrode EL2 may be disposed on the electron transport region ETR. The second electrode EL2 may be a common electrode. The second electrode EL2 may be a cathode or an anode, however, the disclosure is not limited thereto or thereby. As an example, when the first electrode EL1 is the anode, the second electrode EL2 may be the cathode, and when the first electrode EL1 is the cathode, the second electrode EL2 may be the anode. The second electrode EL2 may be a transmissive electrode, a transflective electrode, or a reflective electrode.

The capping layer CPL may be further disposed on the second electrode EL2. The capping layer CPL may have a single-layer structure or a multi-layer structure. According to an embodiment, the capping layer CPL may be an organic layer or an inorganic layer. As an example, in a case where the capping layer CPL includes an inorganic material, the inorganic material may include SiOₓN_{y}, SiNₓ, SiO_{y}, an alkali metal compound, such as LiF, an alkaline earth metal compound, such as MgF₂, or the like. As an example, in a case where the capping layer CPL includes an organic material, the organic material may include α-NPD, NPB, TPD, m-MTDATA, Alq₃, CuPc, TPD15(N4,N4,N4’,N4’-tetra (biphenyl-4-yl) biphenyl-4,4’-diamine), TCTA(4,4’,4”- Tris (carbazol-9-yl) triphenylamine), or the like or may include an epoxy resin or an acrylate, such as methacrylate, however, embodiments are not limited thereto or thereby.

The capping layer CPL may have a refractive index greater than or equal to about 1.6. For example, the refractive index of the capping layer CPL may be greater than or equal to about 1.6 with respect to the light having the wavelength range greater than or equal to about 550 nm and smaller than or equal to about 660 nm.

The encapsulation layer TFE may be disposed on the pixel definition layer PDL and may cover the light emitting element OLED. The encapsulation layer TFE may be disposed on the capping layer CPL and may fill a portion of the pixel opening OH. The encapsulation layer TFE may protect the light emitting element OLED from moisture and oxygen and may protect the light emitting element OLED from a foreign substance, such as dust particles.

FIG. 9 shows the encapsulation layer TFE as a single layer, however, the encapsulation layer TFE may include at least one organic layer, may include at least one inorganic layer, or may include the organic layer and inorganic layer. The encapsulation layer TFE may have a thin film encapsulation layer structure including at least one organic layer and at least one inorganic layer. As an example, the encapsulation layer TFE may have a structure in which the organic layer and the inorganic layer are alternately stacked with each other or the inorganic layer, the organic layer, and the inorganic layer are sequentially stacked.

The inorganic layer included in the encapsulation layer TFE may include a silicon nitride layer, a silicon oxynitride layer, a silicon oxide layer, a titanium oxide layer, or an aluminum oxide layer, however, embodiments are not limited thereto. The organic layer included in the encapsulation layer TFE may include an acrylic-based organic layer, however, embodiments are not limited thereto.

The sensor layer TU may be disposed between the display panel DP and the light control layer AR in the display module DM. The sensor layer TU may obtain information required to generate images in the display panel DP in response to an external input applied thereto. The external input may include a user input. The user input may include various forms of external inputs, such as a part of a user’s body, light, heat, pen, or pressure.

The sensor layer TU may include a sensor base layer BS-TU, a first conductive layer SP1, an inorganic insulating layer IL, a second conductive layer SP2, and an organic insulating layer OL. The first conductive layer SP1 may be disposed on the sensor base layer BS-TU. The inorganic insulating layer IL may cover the first conductive layer SP1 and may be disposed on the sensor base layer BS-TU and the first conductive layer SP1. The second conductive layer SP2 may be disposed on the inorganic insulating layer IL. The organic insulating layer OL may cover the second conductive layer SP2 and may be disposed on the inorganic insulating layer IL and the second conductive layer SP2.

The sensor base layer BS-TU may be an inorganic layer including one of silicon nitride, silicon oxynitride, and silicon oxide. According to an embodiment, the sensor base layer BS-TU may be an organic layer including an epoxy resin, an acrylic resin, or an imide-based resin. The sensor base layer BS-TU may have a single-layer structure or a multi-layer structure of layers stacked in the third direction DR3. The sensor base layer BS-TU may be disposed on (e.g., directly on) the encapsulation layer TFE.

Each of the first conductive layer SP1 and the second conductive layer SP2 may have a single-layer structure or a multi-layer structure of layers stacked in the third direction DR3. The conductive layers SP1 and SP2 having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), or indium zinc tin oxide (IZTO). For example, the transparent conductive layer may include a conductive polymer (e.g., PEDOT), a metal nanowire, and a graphene.

The conductive layers SP1 and SP2 having the multi-layer structure may include a plurality of metal layers. The metal layers may have a three-layer structure of titanium(Ti)/aluminum(Al)/titanium(Ti). The conductive layers SP1 and SP2 having the multi-layer structure may include at least one metal layer and at least one transparent conductive layer.

The inorganic insulating layer IL may include at least one of aluminum oxide, titanium oxide, silicon oxide, silicon oxynitride, zirconium oxide, and hafnium oxide.

A contact hole CN may be defined through (or formed in) the inorganic insulating layer IL. The first conductive layer SP1 and the second conductive layer SP2 may be electrically connected to each other through the contact hole CN. The contact hole CN may be filled with a material of the second conductive layer SP2.

The organic insulating layer OL may cover the inorganic insulating layer IL and the second conductive layer SP2. The organic insulating layer OL may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The display module DM may include the light shielding area NPXA and the pixel areas PXA-R, PXA-G, and PXA-B. Each of the pixel areas PXA-R, PXA-G, and PXA-B may be an area from which a light generated by a corresponding light emitting element among the light emitting elements ED-1, ED-2, and ED-3 is emitted. The pixel areas PXA-R, PXA-G, and PXA-B may be spaced apart from each other when viewed in a plane (or in plan view).

Each of the pixel areas PXA-R, PXA-G, and PXA-B may be defined by the pixel definition layer PDL. The light shielding area NPXA may correspond to an area between the pixel areas PXA-R, PXA-G, and PXA-B adjacent to each other and may correspond to the pixel definition layer PDL. Each of the pixel areas PXA-R, PXA-G, and PXA-B may correspond to the pixel. The pixel definition layer PDL may be defined to distinguish the light emitting elements ED-1, ED-2, and ED-3 from each other. The light emitting layers EML-R, EML-G, and EML-B of the light emitting elements ED-1, ED-2, and ED-3 may be disposed in the pixel openings OH defined through (or formed in) the pixel definition layer PDL to be distinguished from each other.

The pixel areas PXA-R, PXA-G, and PXA-B may be grouped into a plurality of groups according to the colors of the lights generated by the light emitting elements ED-1, ED-2, and ED-3. The display module DM shown in FIGS. 8 and 9 includes three pixel areas PXA-R, PXA-G, and PXA-B respectively emitting red, green, and blue lights. As an example, the display module DM may include the first pixel area PXA-R, the second pixel area PXA-G, and the third pixel area PXA-B, which are distinguished from each other. According to an embodiment, the first pixel area PXA-R may be referred to as a red pixel area, the second pixel area PXA-G may be referred to as a green pixel area, and the third pixel area PXA-B may be referred to as a blue pixel area. In the display module DM, a group including one first pixel area PXA-R, one second pixel area PXA-G, and one third pixel area PXA-B may be referred to as a unit pixel group PXG. According to an embodiment, at least one of the first pixel area PXA-R, the second pixel area PXA-G, and the third pixel area PXA-B included in the unit pixel group PXG may be provided in plural. As an example, the unit pixel group PXG may include two third pixel areas PXA-B, one first pixel area PXA-R, and one second pixel area PXA-G.

According to an embodiment, the light emitting elements ED-1, ED-2, and ED-3 of the display module DM may emit lights having different wavelength ranges from each other. As an example, the display module DM may include the first light emitting element ED-1 emitting the red light, the second light emitting element ED-2 emitting the green light, and the third light emitting element ED-3 emitting the blue light. For example, the red pixel area PXA-R, the green pixel area PXA-G, and the blue pixel area PXA-B of the display module DM may correspond to the first light emitting element ED-1, the second light emitting element ED-2, and the third light emitting element ED-3, respectively.

However, the disclosure is not limited thereto or thereby, and the first, second, and third light emitting elements ED-1, ED-2, and ED-3 may emit lights having the same wavelength range as each other, or at least one of the first, second, and third light emitting elements ED-1, ED-2, and ED-3 may emit a light having a wavelength range different from each other. As an example, all of the first, second, and third light emitting elements ED-1, ED-2, and ED-3 may emit the blue light.

According to an embodiment, the pixel areas PXA-R, PXA-G, and PXA-B of the display module DM may be arranged in a stripe form. Referring to FIG. 8, each of a plurality of red pixel areas PXA-R, a plurality of blue pixel areas PXA-B, and a plurality of green pixel areas PXA-G may be arranged in the first direction DR1. For example, the pixel areas may be sequentially arranged in the order of the red pixel area PXA-R, the green pixel area PXA-G, and the blue pixel area PXA-B, and the pixel areas may be arranged in a repetitive manner in the second direction DR2.

In FIGS. 8 and 9, the pixel areas PXA-R, PXA-G, and PXA-B are shown to be similar in size, however, embodiments are not limited thereto or thereby. According to an embodiment, the sizes of the pixel areas PXA-R, PXA-G, and PXA-B may be different from each other according to the wavelength ranges of the lights emitted therefrom. According to an embodiment, the size of the green pixel area PXA-G may be smaller than the size of the blue pixel area PXA-B. The sizes of the pixel areas PXA-R, PXA-G, and PXA-B may refer to sizes when viewed in the plane defined by the first direction DR1 and the second direction DR2.

The arrangement of the pixel areas PXA-R, PXA-G, and PXA-B is not limited to that shown in FIG. 8, and the order in which the red pixel area PXA-R, the blue pixel area PXA-B, and the green pixel area PXA-G are arranged may be provided in various combinations according to characteristics of display quality required for the display module DM. As an example, the pixel areas PXA-R, PXA-G, and PXA-B may be arranged in a PenTile^{TM} matrix or a Diamond Pixel^{TM} matrix.

Referring to FIG. 9, the light control layer AR may include a first refractive layer RFL1 and a second refractive layer RFL2. Each of the light emitting elements ED-1, ED-2, and ED-3 may overlap each of the first refractive layer RFL1 and the second refractive layer RFL2 when viewed in the plane (or in plan view).

The first refractive layer RFL1 may be disposed on the display panel DP. The first refractive layer RFL1 may be disposed on the sensor layer TU. The first refractive layer RFL1 may be disposed on (e.g., directly on) the sensor layer TU. The first refractive layer RFL1 may have a refractive index greater than or equal to about 1.2 and smaller than or equal to about 1.5 (or in a range of about 1.2 to about 1.5) with respect to a visible light. As an example, the refractive index of the first refractive layer RFL1 with respect to the visible light may be about 1.34. The first refractive layer RFL1 may have an extinction coefficient of zero (0) with respect to the visible light. The first refractive layer RFL1 may include at least one of SiO₂ and MgF₂. As an example, the first refractive layer RFL1 may include SiO₂. The first refractive layer RFL1 may have a thickness T1 greater than or equal to about 10 nm and smaller than or equal to about 500 nm (or in a range of about 10 nm to about 500 nm) . As an example, the thickness T1 of the first refractive layer RFL1 may be about 200 nm.

In the disclosure, the refractive index may be the square root of the product of permittivity and permeability, and the refractive index of a material in nature may always be a positive value. In the disclosure, the extinction coefficient may be a value that represents a degree to which the intensity of light decreases as the light passes through a medium, and the extinction coefficient may be a value obtained by dividing -log(lₜ/l₀) by the product of C and d when l₀ denotes an intensity of the light before passing through the medium, lₜ denotes an intensity of the light after passing through the medium, C denotes a concentration of a substance that absorbs the light in the medium, and d denotes a thickness of the medium through which the light passes. When an extinction coefficient of a material is large, a medium is more likely to absorb light, and when the extinction coefficient of the material is small, the medium is more likely to reflect the light.

The second refractive layer RFL2 may be disposed on the first refractive layer RFL1. The second refractive layer RFL2 may be disposed on (e.g., directly on) the first refractive layer RFL1. The second refractive layer RFL2 may have a refractive index greater than or equal to about -2.0 and smaller than or equal to about -0.1 (or in a range of about -2.0 to about -0.1) with respect to the visible light. As an example, the refractive index of the second refractive layer RFL2 may be about -0.4 with respect to the visible light. The second refractive layer RFL2 may have an extinction coefficient of zero (0) with respect to the visible light. The second refractive layer RFL2 may include a metamaterial. The metamaterial may be a concept corresponding to an ordinary material and refers to a medium that has positive, zero (0), or negative permittivity, negative permeability, or a negative refractive index. For example, a refractive index varies according to a frequency, but in the case of the metamaterial, the metamaterial may exhibit a refractive index of zero (0) or a negative value in a specific frequency range. The second refractive layer RFL2 of the disclosure may include the metamaterial having the negative refractive index for the visible light, and thus, the front luminance rate of the electronic device may be improved, and the security of the electronic device may be enhanced.

The second refractive layer RFL2 may include at least one of a metal, a metal oxide, and a metal halide. The second refractive layer RFL2 may have a three-dimensional (3D) column structure. The 3D column structure may be a three-dimensional array structure in which cylindrical shapes extending in one direction are spaced apart from each other when viewed in the plane (or in plan view), and when a light is obliquely incident to the second refractive layer RFL2 having the 3D column structure, the light may be reflected or refracted. For example, the second refractive layer RFL2 may have the negative refractive index. The second refractive layer RFL2 may include at least one of Au, TiO₂, SiO₂, MgF, and Ta₂O₅. As an example, the second refractive layer RFL2 may include MgF. The second refractive layer RFL2 may have a thickness T2 greater than or equal to about 10 nm and smaller than or equal to about 300 nm (or in a range of about 10 nm to about 300 nm) . As an example, the thickness T2 of the second refractive layer RFL2 may be about 100 nm.

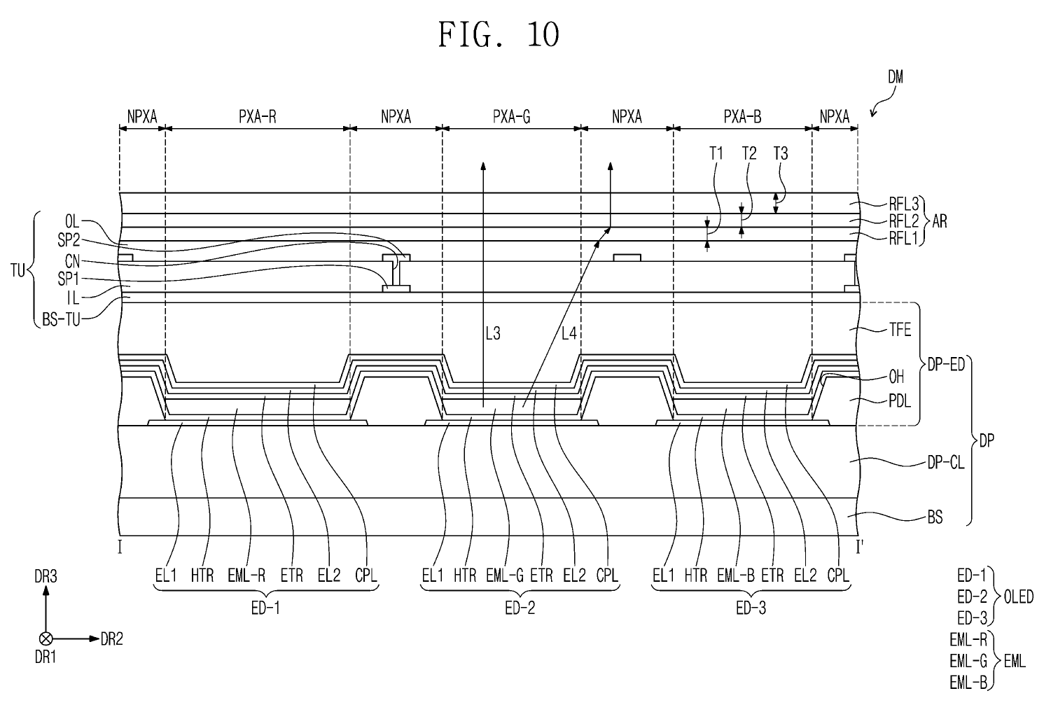

Referring to FIG. 10, the light control layer AR may further include a third refractive layer RFL3. Each of the light emitting elements ED-1, ED-2, and ED-3 may overlap the third refractive layer RFL3 when viewed in the plane (or in plan view).

The third refractive layer RFL3 may be disposed on the second refractive layer RFL2. The third refractive layer RFL3 may be disposed on (e.g., directly on) the second refractive layer RFL2. The third refractive layer RFL3 may have a refractive index greater than or equal to about 1.2 or smaller than or equal to about 1.5 (or in a range of about 1.2 to about 1.5) with respect to the visible light. As an example, the refractive index of the third refractive layer RFL3 may be about 1.34 with respect to the visible light. The third refractive layer RFL3 may have an extinction coefficient of zero (0) with respect to the visible light. The third refractive layer RFL3 may include at least one of SiO₂ and MgF₂. As an example, the third refractive layer RFL3 may include SiO₂. The third refractive layer RFL3 may have a thickness T3 greater than or equal to about 10 nm and smaller than or equal to about 500 nm (or in a range of about 10 nm to about 500 nm). As an example, the thickness T3 of the third refractive layer RFL3 may be about 200 nm.

FIG. 9 shows the path of a first light L1 and a second light L2 emitted from the second light emitting layer EML-G as the first light L1 and the second light L2 enter the light control layer AR.

Referring to FIG. 9, the first light L1 may travel or transmit in a direction substantially parallel to the third direction DR3 and may be viewed from the front of the display module DM after passing through the first refractive layer RFL1 and the second refractive layer RFL2.

The second light L2 may travel or transmit in a direction between the second direction DR2 and the third direction DR3 and may be refracted by the first refractive layer RFL1. Since the first refractive layer RFL1 has a positive refractive index, the second light L2 may continue to travel or transmit between the second direction DR2 and the third direction DR3, but in a direction closer to the second direction DR2 compared to its direction before being refracted by the first refractive layer RFL1. The second light L2 may be refracted by the second refractive layer RFL2. Since the second refractive layer RFL2 has a negative refractive index, the second light L2 may travel or transmit in the third direction DR3. The second light L2 refracted by the second refractive layer RFL2 may be viewed from the front of the display module DM.

For example, when the light emitted from the second light emitting layer EML-G travels or transmits between the up-down direction DR1 and the third direction DR3, the light emitted from the second light emitting layer EML-G may be refracted by each of the first refractive layer RFL1 and the second refractive layer RFL2 and may travel or transmit in the third direction DR3. As a result, the light emitted from the second light emitting layer EML-G may be viewed from the front of the display module DM.

The light emitted from the display module DM of the disclosure may pass through the first refractive layer RFL1 having the positive refractive index and the second refractive layer RFL2 having the negative refractive index, may be viewed from the front of the display module DM, and may not be viewed from the lateral sides of the display module DM. Therefore, the front luminance rate of the display module DM may increase, and the security of the display module DM may be ensured or enhanced.

FIG. 10 shows the path of a third light L3 and a fourth light L4 emitted from the second light emitting layer EML-G as the third light L3 and the fourth light L4 enter the light control layer AR.

Referring to FIG. 10, the third light L3 may travel or transmit in the direction substantially parallel to the third direction DR3 and may be viewed from the front of the display module DM after passing through the first refractive layer RFL1, the second refractive layer RFL2, and the third refractive layer RFL3.

The fourth light L4 may travel or transmit between the second direction DR2 and the third direction DR3 and may be refracted by the first refractive layer RFL1. Since the first refractive layer RFL1 may have the positive refractive index, the fourth light L4 may continue to travel or transmit between the second direction DR2 and the third direction DR3, but in a direction closer to the second direction DR2 compared to its direction before being refracted by the first refractive layer RFL1. The fourth light L4 may be refracted by the second refractive layer RFL2. Since the second refractive layer RFL2 has the negative refractive index, the fourth light L4 may travel or transmit in the third direction DR3. The fourth light L4 refracted by the second refractive layer RFL2 may be viewed from the front of the display module DM after passing through the third refractive layer RFL3.

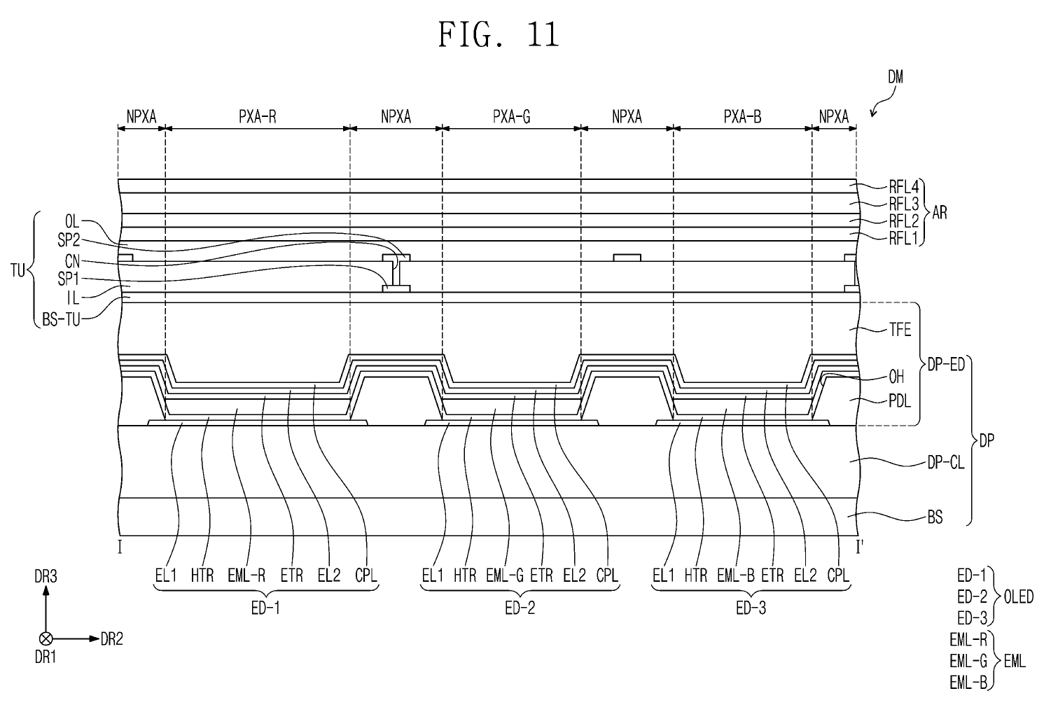

Referring to FIG. 11, unlike the display module DM shown in FIGS. 9 and 10, the light control layer AR may further include a fourth refractive layer RFL4.

The fourth refractive layer RFL4 may be disposed on the third refractive layer RFL3. The fourth refractive layer RFL4 may be disposed on (e.g., directly on) the third refractive layer RFL3. The fourth refractive layer RFL4 may have a refractive index greater than or equal to about -2.0 and smaller than or equal to about -0.1 (or in a range of about -2.0 to about -0.1) with respect to the visible light. As an example, the refractive index of the fourth refractive layer RFL4 with respect to the visible light may be about -0.4. The fourth refractive layer RFL4 may have an extinction coefficient of zero (0) with respect to the visible light. The fourth refractive layer RFL4 may include the metamaterial.

The fourth refractive layer RFL4 may include at least one of a metal, a metal oxide, and a metal halide. The fourth refractive layer RFL4 may have a 3D column structure. The fourth refractive layer RFL4 may include at least one of Au, TiO₂, SiO₂, MgF, and Ta₂O₅. As an example, the fourth refractive layer RFL4 may include MgF. The fourth refractive layer RFL4 may have a thickness greater than or equal to about 10 nm and smaller than or equal to about 300 nm (or in a range of about 10 nm to about 300 nm). As an example, the thickness of the fourth refractive layer RFL4 may be about 100 nm.

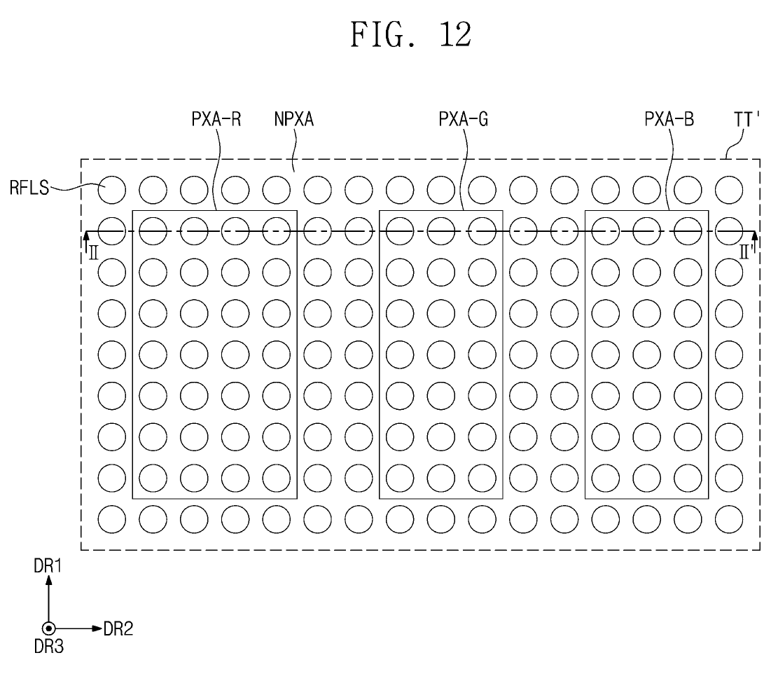

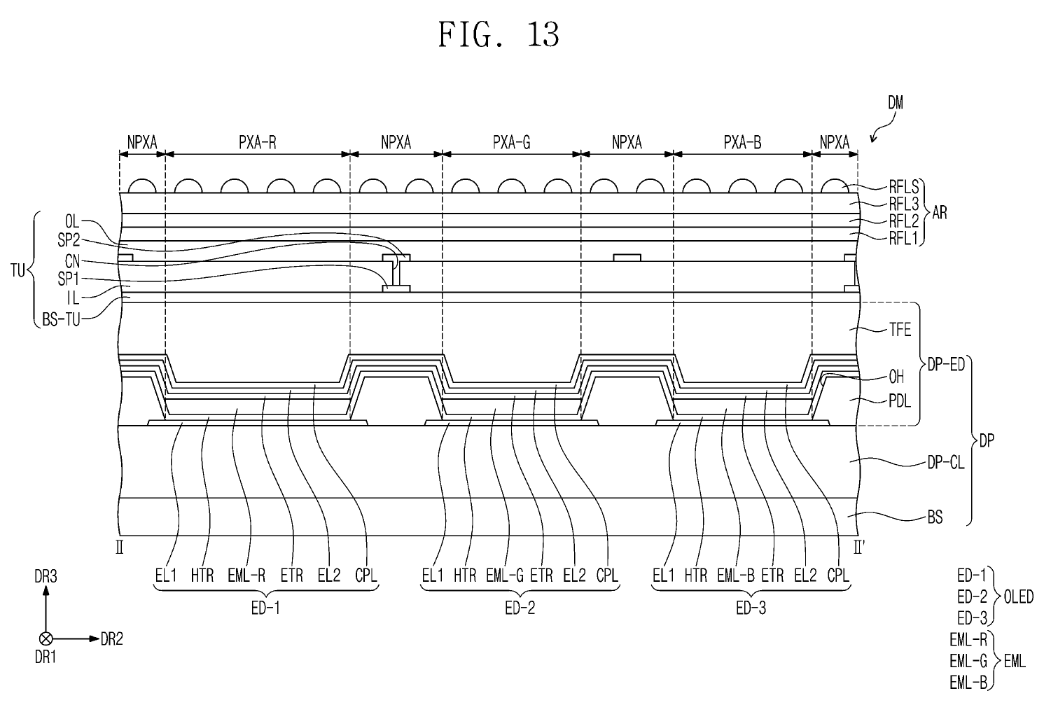

FIG. 12 is an enlarged plan view illustrating area TT’ of FIG. 8. FIG. 13 is a cross-sectional view taken along line II-II’ of FIG. 12.

Referring to FIGS. 12 and 13, the light control layer AR may further include a plurality of refractive lenses RFLS. The refractive lens RFLS may have a semicircular shape convex toward the third direction DR3 when viewed in the cross-section. The refractive lenses RFLS may be disposed on the third refractive layer RFL3. The refractive lenses RFLS may be disposed on (e.g., directly on) the third refractive layer RFL3. The refractive lenses RFLS may overlap the light shielding area NPXA and the pixel areas PXA-R, PXA-G, and PXA-B when viewed in the plane (or in plan view). FIG. 12 illustrates twenty eight refractive lenses RFLS overlapping the first pixel area PXA-R as a representative example, however, the number of refractive lenses RFLS overlapping the first pixel area PXA-R may be changed and may be equally applied to each of the light shielding area NPXA, the second pixel area PXA-G, and the third pixel area PXA-B. FIG. 12 illustrates a structure in which the refractive lenses RFLS are arranged in each of the first direction DR1 and the second direction DR2, however, according to an embodiment, the refractive lenses RFLS may be irregularly or randomly arranged.

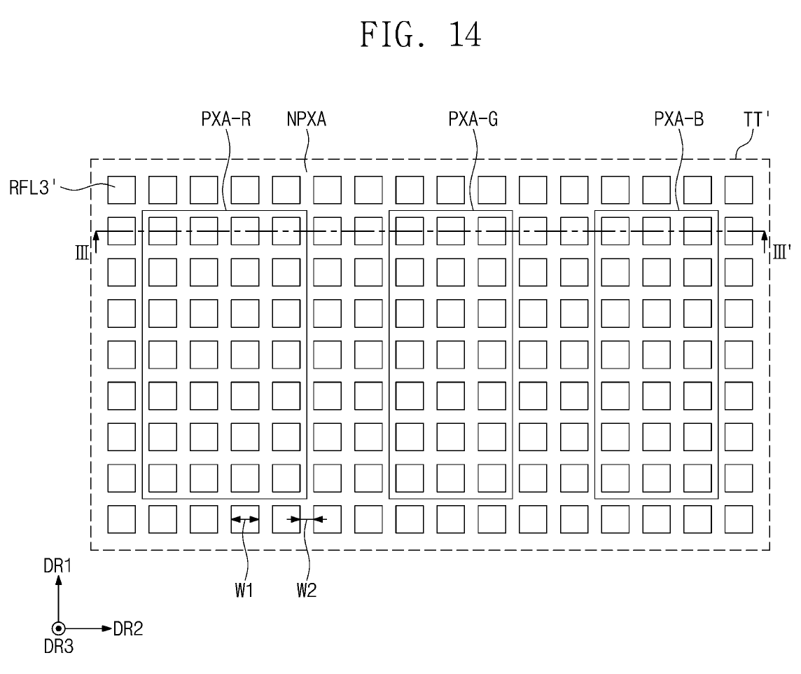

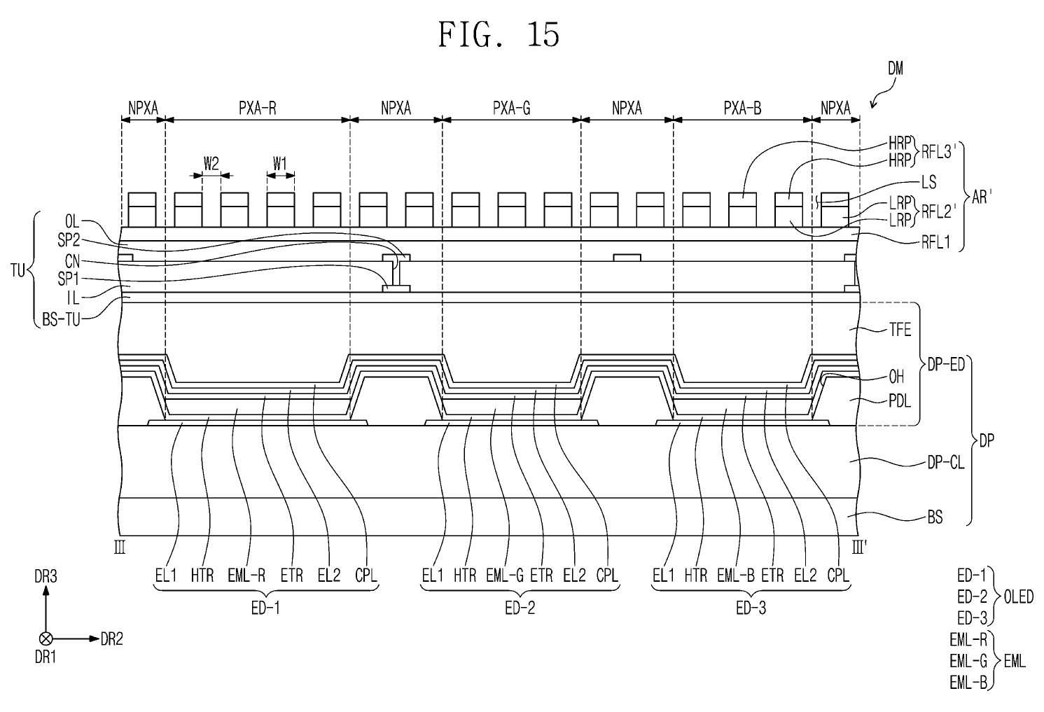

FIG. 14 is an enlarged plan view illustrating the area TT’ of FIG. 8. FIG. 15 is a cross-sectional view taken along line III-III’ of FIG. 14.

Referring to FIGS. 14 and 15, a light control layer AR’ may include a first refractive layer RFL1, a second refractive layer RFL2’, and a third refractive layer RFL3’. The second refractive layer RFL2’ may include a plurality of lower refractive patterns LRP. Each of the lower refractive patterns LRP may have a quadrangular shape defined by sides extending in the first direction DR1 and the second direction DR2 when viewed in the plane (or in plan view). A side of each of the lower refractive patterns LRP may have a width W1 greater than or equal to about 10 nm and smaller than or equal to about 500 nm (or in a range of about 10 nm to about 500 nm) when viewed in the plane (or in plan view). As an example, the width W1 of the side of each of the lower refractive patterns LRP may be about 100 nm when viewed in the plane (or in plan view). The lower refractive patterns LRP may be spaced apart from each other, and a separation space LS may be defined between the lower refractive patterns LRP. A portion of an upper surface of the first refractive layer RFL1 may be exposed through the separation space LS. The separation space LS may have a width W2 that is substantially the same as a separation distance between the lower refractive patterns LRP when viewed in the plane (or in plan view). The width W2 of the separation space LS may be greater than or equal to about 50 nm and smaller than or equal to about 500 nm (or in a range of about 50 nm to about 500 nm). As an example, the width W2 of the separation space LS may be about 200 nm.

The third refractive layer RFL3’ may include a plurality of upper refractive patterns HRP. The upper refractive patterns HRP may be disposed on the lower refractive patterns LRP, respectively. The upper refractive patterns HRP may be disposed on the lower refractive patterns LRP in a one-to-one correspondence. The upper refractive patterns HRP may be deposited by a glancing angle deposition method. The upper refractive pattern HRP may have substantially the same area as the lower refractive pattern LRP when viewed in the plane (or in plan view). The upper refractive patterns HRP may not overlap the separation space LS when viewed in the plane (or in plan view). Each of the upper refractive patterns HRP may have a thickness greater than or equal to about 10 nm and smaller than or equal to about 500 nm (or in a range of about 10 nm to about 500 nm). As an example, the thickness of the upper refractive pattern HRP may be about 200 nm.

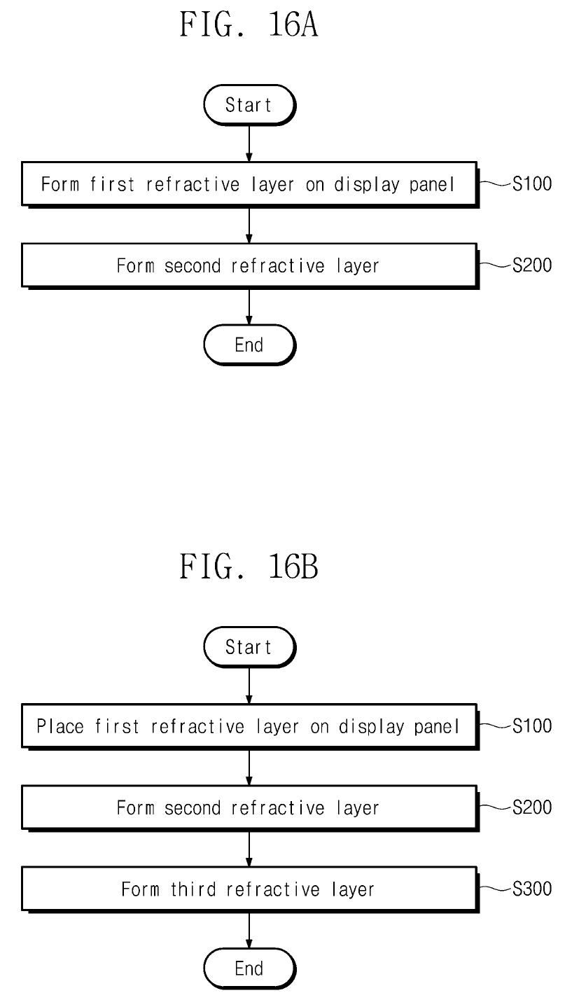

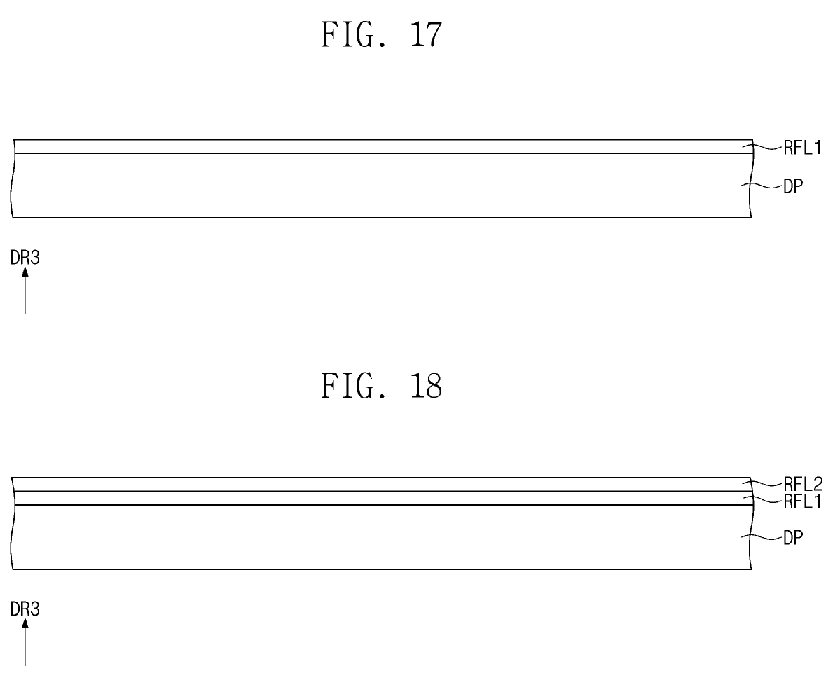

The display module may be manufactured by a manufacturing method of the display module according to an embodiment of the disclosure. FIGS. 16A and 16B are flowcharts illustrating the method of manufacturing the display module according to embodiments of the disclosure. FIGS. 17 to 22 are cross-sectional views illustrating the method of manufacturing the display module according to an embodiment of the disclosure. Hereinafter, in FIGS. 16A to 22, detailed descriptions of the components previously described with reference to FIGS. 5 to 15 will be omitted.

Referring to FIG. 16A, the manufacturing method of the display module may include forming the first refractive layer on the display panel (S100) and forming the second refractive layer (S200).

Referring to FIG. 16B, the manufacturing method of the display module may further include forming the third refractive layer (S300). The forming of the third refractive layer (S300) may be performed after the forming of the second refractive layer (S200).

Referring to FIG. 17, the first refractive layer RFL1 may be formed (e.g., directly formed) on the display panel DP in the forming of the first refractive layer RFL1 on the display panel DP. The first refractive layer RFL1 may be formed by various methods, such as a vacuum deposition method, a spin coating method, a cast method, a Langmuir-Blodgett (LB) method, an inkjet printing method, a laser printing method, a Laser Induced Thermal Imaging (LITI) method, etc. As an example, the first refractive layer RFL1 may be formed by the inkjet printing method. The sensor layer TU (refer to FIG. 9) may be disposed between the first refractive layer RFL1 and the display panel DP, but the sensor layer TU (refer to FIG. 9) is omitted in FIGS. 17 to 22. When the sensor layer TU (refer to FIG. 9) is disposed between the first refractive layer RFL1 and the display panel DP, the first refractive layer RFL1 may be formed (e.g., directly formed) on the sensor layer TU (refer to FIG. 9).

The first refractive layer RFL1 may include at least one of SiO₂ and MgF₂. As an example, the first refractive layer RFL1 may include SiO₂. The refractive index of the first refractive layer RFL1 with respect to the visible light may be greater than or equal to about 1.2 and smaller than or equal to about 1.5 (or in a range of about 1.2 to about 1.5). As an example, the refractive index of the first refractive layer RFL1 with respect to the visible light may be about 1.34. The extinction coefficient of the first refractive layer RFL1 with respect to the visible light may be zero (0).

Referring to FIG. 18, the second refractive layer RFL2 may be formed (e.g., directly formed) on the first refractive layer RFL1 in the forming of the second refractive layer RFL2. The second refractive layer RFL2 may be deposited by a glancing angle deposition method. The glancing angle deposition method refers to a deposition method in which a vapor is incident onto a substrate at an angle greater than 0° relative to a perpendicular line to the substrate, unlike a conventional process where the vapor is incident perpendicularly to the substrate.

The second refractive layer RFL2 may include at least one of the metal, the metal oxide, and the metal halide. The second refractive layer RFL2 may have the 3D column structure. The second refractive layer RFL2 may include at least one of Au, TiO₂, SiO₂, MgF, and Ta₂O₅. As an example, the second refractive layer RFL2 may include MgF. The refractive index of the second refractive layer RFL2 with respect to the visible light may be greater than or equal to about -2.0 and smaller than or equal to about -0.1 (or in a range of about -2.0 to about -0.1). As an example, the refractive index of the second refractive layer RFL2 with respect to the visible light may be about -0.4. The extinction coefficient of the second refractive layer RFL2 with respect to the visible light may be zero (0). The second refractive layer RFL2 may include the metamaterial. The second refractive layer RFL2 may include the metamaterial having the negative refractive index with respect to the visible light. Thus, the front luminance rate of the electronic device may be improved, and the security of the electronic device may be enhanced.

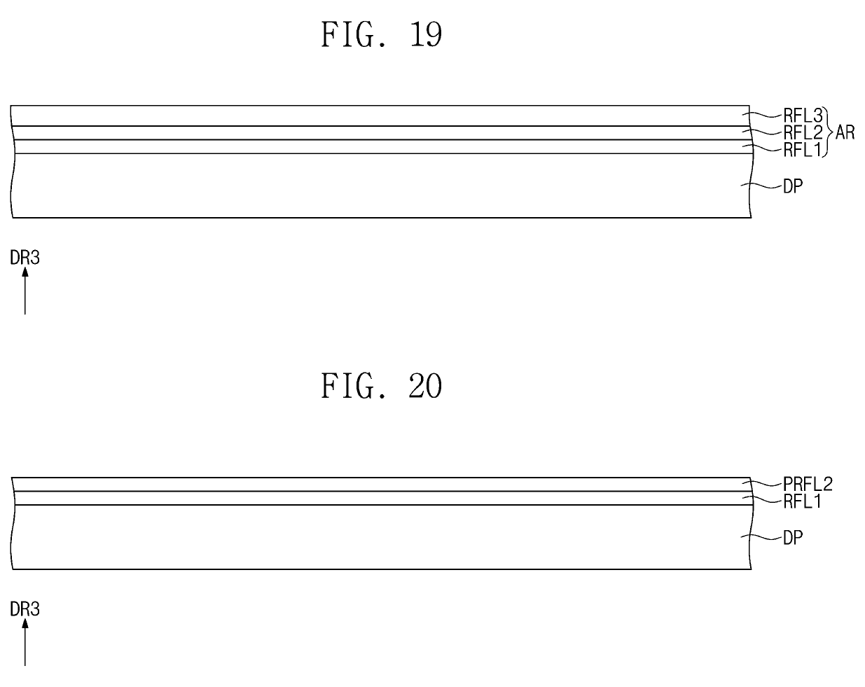

Referring to FIG. 19, the third refractive layer RFL3 may be formed (e.g., directly formed) on the second refractive layer RFL2 in the forming of the third refractive layer RFL3. The third refractive layer RFL3 may be formed by various methods, such as a vacuum deposition method, a spin coating method, a cast method, a Langmuir-Blodgett (LB) method, an inkjet printing method, a laser printing method, a Laser Induced Thermal Imaging (LITI) method, etc. As an example, the third refractive layer RFL3 may be formed by the inkjet printing method. The third refractive layer RFL3 may include at least one of SiO₂ and MgF₂. As an example, the third refractive layer RFL3 may include SiO₂. The refractive index of the third refractive layer RFL3 with respect to the visible light may be greater than or equal to about 1.2 and smaller than or equal to about 1.5 (or in a range of about 1.2 to about 1.5). As an example, the refractive index of the third refractive layer RFL3 with respect to the visible light may be about 1.34. The extinction coefficient of the third refractive layer RFL3 with respect to the visible light may be zero (0).

Unlike the manufacturing method of the display module shown in FIGS. 17 to 19, the manufacturing method of the display module shown in FIGS. 20 to 22 illustrates the manufacturing method of the display module in which the second refractive layer includes the lower refractive pattern and the third refractive layer includes the upper refractive pattern.

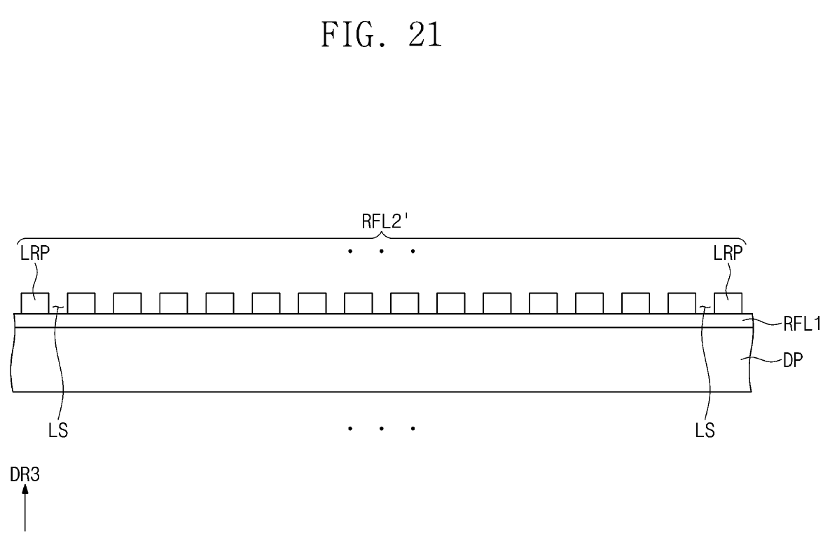

Referring to FIGS. 20 and 21, the forming of the second refractive layer RFL2’ may include forming a preliminary second refractive layer PRFL2 on the first refractive layer RFL1 and forming the lower refractive patterns LRP.

In the forming of the preliminary second refractive layer PRFL2 on the first refractive layer RFL1, the preliminary second refractive layer PRFL2 may be formed through the same process as the second refractive layer RFL2 shown in FIG. 17. In the forming of the lower refractive patterns LRP, a portion of the preliminary second refractive layer PRFL2 may be etched, and thus, the separation space LS may be formed. The lower refractive patterns LRP may be spaced apart from each other, and the separation space LS may be formed between the lower refractive patterns LRP.

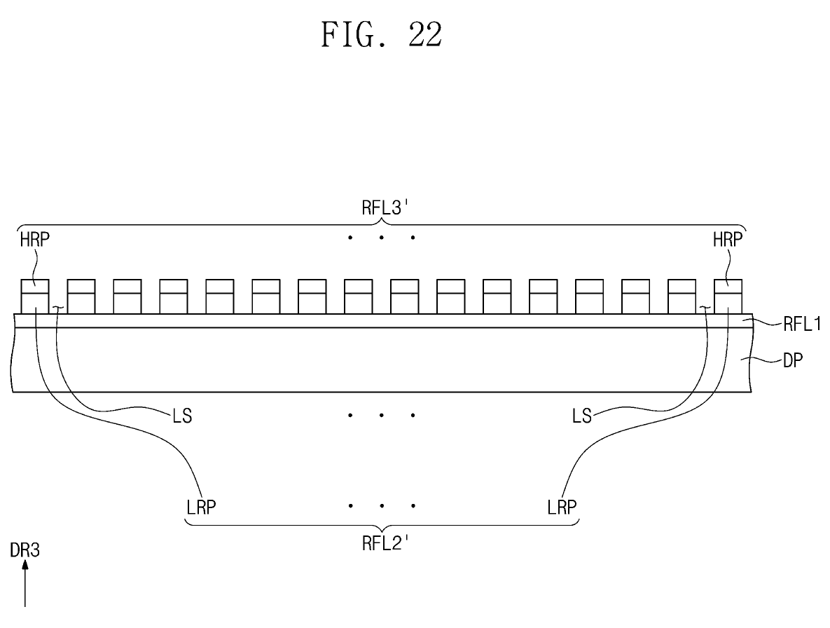

Referring to FIG. 22, in the forming of the third refractive layer RFL3’, the upper refractive patterns HRP may be formed on the lower refractive patterns LRP, respectively. The upper refractive patterns HRP may be deposited by the glancing angle deposition method.

Hereinafter, an intensity (%) and a transmittance (%) of light of the display module according to an embodiment of the disclosure are compared with those of a display module of a Comparative Example according to a viewing angle (°).

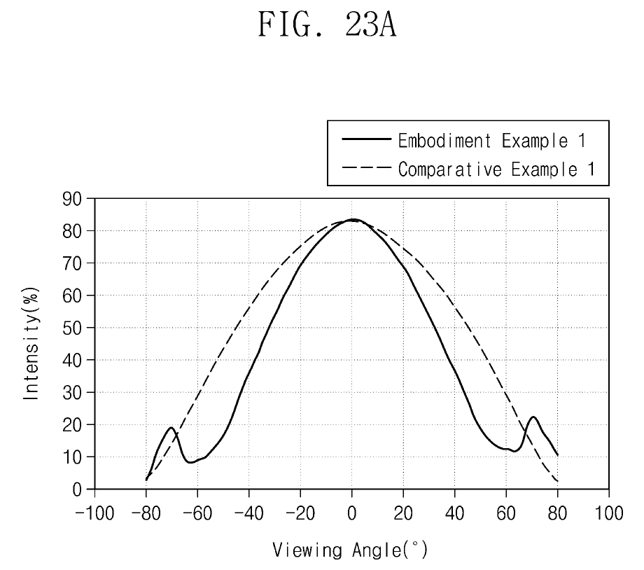

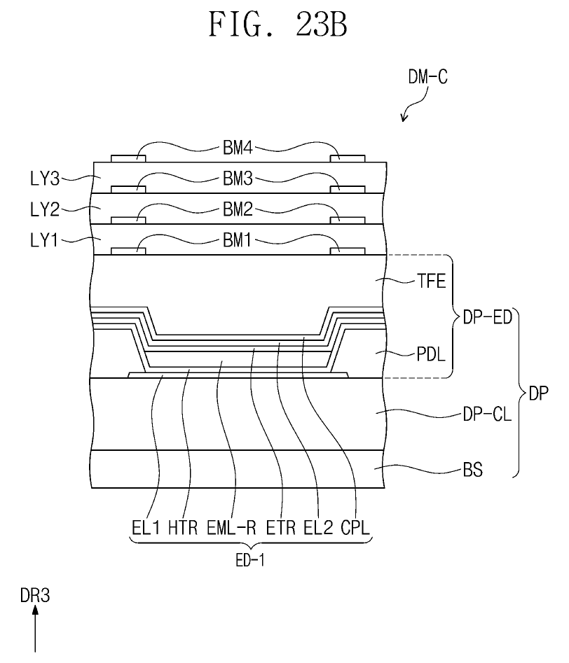

FIG. 23A is a graph illustrating results of simulating the intensity of light according to the viewing angle of each of the display module of Comparative Example 1 and the display module of Example Embodiment 1. FIG. 23B is a cross-sectional view illustrating the display module of Comparative Example 1. In FIG. 23A, as the intensity value of light becomes larger and the shape of a graph becomes closer to a pointed shape with the viewing angle of 0° as a reference, it is interpreted that the light viewing angle of the display module is improved. An improvement of the viewing angle of the display module means that the security is improved since a ratio of the intensity of light perceived from the front of the display module (e.g., at a viewing angle of 0°) is greater than a ratio of the intensity of light perceived from the lateral sides (e.g., at a viewing angle of 30°). The intensity of light may be a ratio of a light intensity measured at a specific viewing angle to an initial intensity of the light emitted from a light source, e.g., the display module DM. The viewing angle refers to an angle at which the user views the display module based on the thickness direction of the display module.

The display module of Example Embodiment 1 may have the same structure as the display module shown in FIG. 10, the refractive index of the first refractive layer and the third refractive layer with respect to the visible light may be about 1.34, and the refractive index of the second refractive layer with respect to the visible light may be about -0.4.

The display module DM-C of Comparative Example 1 of FIG. 23B includes a first shielding pattern BM1 disposed on a display panel DP, overlapping a pixel definition layer PDL, and aligned with an end of a first light emitting layer EML-R, a first layer LY1 disposed on the display panel DP and covering the first shielding pattern BM1, a second shielding pattern BM2 disposed on the first layer LY1 and overlapping the first shielding pattern BM1, a second layer LY2 disposed on the first layer LY1 and covering the second shielding pattern BM2, a third shielding pattern BM3 disposed on the second layer LY2 and overlapping the second shielding pattern BM2, a third layer LY3 disposed on the second layer LY2 and covering the third shielding pattern BM3, and a fourth shielding pattern BM4 disposed on the third layer LY3 and covering the third shielding pattern BM3. Each of the first, second, third, and fourth shielding patterns BM1, BM2, BM3, and BM4 may include a material that absorbs a light. Each of the first, second, and third layers LY1, LY2, and LY3 may have a refractive index of about 1.58 with respect to the visible light.

The display module of the Example Embodiment 1 may include the second refractive layer including the metamaterial. Accordingly, when compared to the display module of the Comparative Example 1, the light viewing angle of the display module of the Example Embodiment 1 may be improved by about 12% and the security of the display module of the Example Embodiment 1 may be enhanced.

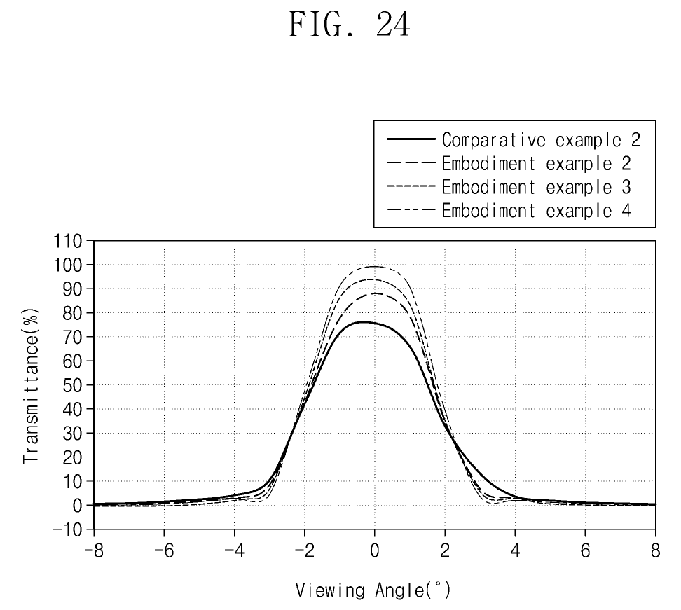

FIG. 24 is a graph illustrating results of simulating the transmittance according to the viewing angle of each of a display module of Comparative Example 2 and display modules of Example Embodiments 2, 3, and 4. In FIG. 24, it is interpreted that the higher the transmittance near the viewing angle of 0°, the better the light efficiency of the display module. The transmittance refers to a ratio of the intensity of light perceived by the user to an initial intensity of light generated from a light source, e.g., display module DM.

The display module of Example Embodiment 2 may have the same structure as the display module shown in FIG. 9. The display module of Example Embodiment 3 may have the same structure as the display module shown in FIG. 10. The display module of Example Embodiment 4 may have the same structure as the display module shown in FIG. 11. The display module of Comparative Example 2 does not include the second refractive layer compared to the display module shown in FIG. 9.

The display modules of Example Embodiments 2 to 4 may have improved transmittance and light efficiency compared to the display module of Comparative Example 2. The display module of Comparative Example 2 has the lowest transmittance, and the display module of Example Embodiment 4 has the highest transmittance.

The display module according to the disclosure may include the first refractive layer and the second refractive layer, which includes the metamaterial. Thus, the light viewing angle and the light efficiency of the display module according to the disclosure may be improved compared to the conventional display module.

Although the embodiments of the disclosure have been described, it is understood that the disclosure is not limited to these embodiments but various changes and modifications can be made by one ordinary skilled in the art within the spirit and scope of the disclosure as hereinafter claimed.

Therefore, the disclosed subject matter is not limited to any single embodiment described herein, and the scope of the disclosure shall be determined according to the attached claims.

What is claimed is:

1. A display module comprising:
a display panel; and
a light control layer on the display panel, the light control layer comprising:
a first refractive layer disposed on the display panel; and
a second refractive layer on the first refractive layer, wherein
the first refractive layer has a refractive index in a range of about 1.2 to about 1.5 with respect to a visible light,
the second refractive layer comprises a metamaterial, and
the second refractive layer has a refractive index in a range of about -2.0 to about -0.1 with respect to the visible light.

2. The display module of claim 1, wherein:
the light control layer further comprises a third refractive layer on the second refractive layer, and
the third refractive layer has a refractive index in a range of about 1.2 to about 1.5 with respect to the visible light.

3. The display module of claim 2, wherein each of the first refractive layer and the third refractive layer comprises at least one of SiO₂ and MgF₂.

4. The display module of claim 2, wherein each of the first refractive layer and the third refractive layer has a thickness in a range of about 10 nm to about 500 nm.

5. The display module of claim 2, wherein the light control layer further comprises a plurality of refractive lenses on the third refractive layer.

6. The display module of claim 5, wherein:
each of the refractive lenses comprises the metamaterial, and
each of the refractive lenses has a refractive index in a range of about -2.0 to about -0.1 with respect to the visible light.

7. The display module of claim 2, wherein:
the light control layer further comprises a fourth refractive layer on the third refractive layer,
the fourth refractive layer comprises the metamaterial, and
the fourth refractive layer has a refractive index in a range of about -2.0 to about -0.1 with respect to the visible light.

8. The display module of claim 2, wherein
the second refractive layer comprises a plurality of lower refractive patterns,
the lower refractive patterns are spaced apart,
a separation space is defined between the lower refractive patterns, and
the third refractive layer comprises a plurality of upper refractive patterns on the lower refractive patterns, respectively.

9. The display module of claim 8, wherein each of the lower refractive patterns has a quadrangular shape in plan view.

10. The display module of claim 9, wherein each of the lower refractive patterns has a side in a range of about 10 nm to about 500 nm in plan view.

11. The display module of claim 8, wherein the lower refractive patterns are spaced apart by a distance in a range of about 50 nm to about 500 nm in plan view.

12. The display module of claim 1, wherein the second refractive layer comprises at least one of a metal, a metal oxide, and a metal halide.

13. The display module of claim 1, wherein the second refractive layer comprises at least one of Au, TiO₂, SiO₂, MgF, and Ta₂O₅.

14. The display module of claim 1, wherein the second refractive layer has an extinction coefficient of zero (0) with respect to the visible light.

15. The display module of claim 1, wherein the second refractive layer has a thickness in a range of about 10 nm to about 300 nm.

16. An electronic device comprising:
a housing;
a display module in the housing; and
a window disposed on the display module, the display module comprising:
a display panel; and
a light control layer on the display panel, the light control layer comprising:
a first refractive layer on the display panel; and
a second refractive layer on the first refractive layer, wherein
the first refractive layer has a refractive in a range of about 1.2 to about 1.5 with respect to a visible light,
the second refractive layer comprises a metamaterial, and
the second refractive layer has a refractive index in a range of about -2.0 to about -0.1 with respect to the visible light.

17. A method of manufacturing a display module, comprising:
forming a first refractive layer on a display panel; and
forming a second refractive layer on the first refractive layer; and
forming a third refractive layer on the second refractive layer after the forming of the second refractive layer, wherein
the first refractive layer has a refractive index in a range of about 1.2 to about 1.5 with respect to a visible light,
the second refractive layer comprises a metamaterial, and
the second refractive layer has a refractive index in a range of about -2.0 to about -0.1 with respect to the visible light.

18. The method of claim 17, wherein the forming of the second refractive layer comprises:
forming a preliminary second refractive layer on the first refractive layer; and
etching a portion of the preliminary second refractive layer to form a plurality of lower refractive patterns spaced apart from each other such that a separation space is defined between the lower refractive patterns, and
wherein the forming of the third refractive layer comprises forming a plurality of upper refractive patterns disposed on the lower refractive patterns, respectively.

19. The method of claim 17, wherein the second refractive layer comprises at least one of Au, TiO₂, SiO₂, MgF, and Ta₂O₅.

20. An electronic device comprising:
a window; and
a display module manufactured by the method of claim 17.
